(19) United States
(12) Patent Application Publication
(10) Pub. No.: US 2008/0286696 A1
(43) Pub. Date: Nov. 20, 2008

(54) Method for manufacturing multilayer printed wiring board

(75) Inventors: Yukihiro Ueno, Hiroshima (JP); Masatoshi Mori, Hiroshima (JP)

Correspondence Address: BIRCH STEWART KOLASCH & BIRCH, PO BOX 747, FALLS CHURCH, VA, 22040-0747, US

(73) Assignee: SHARP KABUSHIKI KAISHA

(21) Appl. No.: 11/987,347

(22) Filed: Nov. 29, 2007

(30) Foreign Application Priority Data
Dec. 1, 2006 (JP) 2006-326007

(51) Int. Cl. G03F 7/20

(52) U.S. Cl. 430/319

(57) ABSTRACT

In one embodiment, the invention has a step of forming an inner layer circuit pattern portion and a lead pattern portion, a step of forming a dummy pattern that indicates the range of the lead pattern portion on the outer layer base material, a step of forming an interlayer adhesive layer on a surface of the outer layer base material where the dummy pattern has been formed, a step of applying, corresponding to the dummy pattern, a resin film to the interlayer adhesive layer, a step of layering the outer layer base material on the inner layer base material via the interlayer adhesive layer with the position of the resin film matched to the position of the lead pattern portion, a step of forming the outer layer circuit pattern portion corresponding to the inner layer circuit pattern portion, and a step of removing the interlayer adhesive layer and the outer layer base material layered on the resin film.

This application claims priority under 35 U.S.C. § 119(a) on Japanese Patent Application No. 2006-326007 filed in Japan on Dec. 1, 2006, the entire contents of which are hereby incorporated by reference.

### BACKGROUND OF THE INVENTION

1. Field of the Invention

The present invention relates to a method for manufacturing a multilayer printed wiring board used in an electronic device or the like, and more specifically a multilayer printed wiring board having two or more conductor layers, with a portion of an outer layer base material removed and a flexible inner layer base material serving as a lead pattern portion.

2. Description of the Related Art

In portable electronic devices such as video cameras and digital cameras, it is necessary to arrange many electronic components in a small internal space, and connect these electronic components by wiring them to each other.

Conventionally, hard printed wiring boards are connected to each other using connectors and cables, but with the object of reliability and controlling impedance of the connections, and reducing volume, multilayer printed wiring boards have been proposed in which a cable portion (a printed wiring board that is flexible and can be bent) and a mounting portion (a hard printed wiring board) are configured as a single printed wiring board.

When mounting electronic components in a cable portion where flexibility is demanded, or installing a cable portion to a case body, handling is better if the mounting portion where the electronic component is mounted has at least some degree of rigidity. As a result, it is necessary that in the multilayer printed wiring board, the mounting portion has both flexibility and rigidity. However, in this case, when the manufacturing process becomes complicated, there are problems such as that distortion occurs at the border of the flexible portion and the rigid portion.

A method for manufacturing a conventional multilayer printed wiring board, referred to as a flex-rigid or rigid-flex multilayer printed wiring board, will be described with reference to FIGS. 15 to 20 (Conventional Example 1) and FIGS. 21 and 22 (Conventional Example 2). With such a multilayer printed wiring board, a portion having suppleness and flexibility used for a cable (referred to below as a flexible portion), and a portion that has a greater number of conductor layers and higher rigidity than the flexible portion, and is where mainly mounting of electronic components is performed (referred to below as a multilayer portion), are included in a single printed wiring board.

In order to simplify the drawings and the description, by way of example, a description is given of a multilayer printed wiring board with a configuration in which the multilayer portion has a total of four layers, and the flexible portion has one layer, but the processing procedure is the same in the case of a multilayer printed wiring board with a greater number of layers.

FIG. 15 is a cross-sectional view that shows the configuration of an inner layer base material applied in the method for manufacturing a multilayer printed wiring board according to Conventional Example 1.

An inner layer base material 110 is configured with a flexible inner layer insulating base material 111 that serves as an inner layer core, and inner layer conductor layers 112 and 113 formed on both faces of the inner layer insulating base material 111. The inner layer insulating base material 111, for example, is an insulating resin film such as a polyimide, polyether ketone, or crystal polymer. Also, the inner layer conductor layers 112 and 113 are obtained by layering, for example, a conductor metal (metal layer) such as copper foil on the surface of the inner layer insulating base material 111.

A portion of the inner layer base material 110 is a flexible portion employed as a cable. Also, the inner layer base material 110 is commercially available as double-sided flexible wiring board material.

FIG. 16 is a cross-sectional view that shows a state in which a resist mask has been formed in order to form the inner layer circuit pattern portion and the lead pattern portion in the inner layer base material shown in FIG. 15. FIG. 17 is a cross-sectional view that shows a state in which an inner layer circuit pattern portion and a lead pattern portion have been formed in the inner layer base material, employing the resist mask shown in FIG. 16.

An etching resist is applied to the surface of the conductor layers 112 and 113 by employing a circuit pattern formation method (such as a photolithography method), thus forming an etching resist 140 that corresponds to a circuit pattern (FIG. 16).

Next, by etching (patterning) the conductor layers 112 and 113 with a suitable etchant, an inner layer circuit pattern 112c, an inner layer circuit pattern 113c, and a lead pattern 112t are formed, and then the etching resist 140 is peeled away (FIG. 17).

The inner layer circuit pattern 112c and the inner layer circuit pattern 113c constitute an inner layer circuit pattern portion Acf The lead pattern 112t constitutes a lead pattern portion At (flexible portion) extended from the inner layer circuit pattern portion Acf. That is, by patterning the conductor layers 112 and 113 of the inner layer base material 110, the inner layer circuit pattern portion Acf and the lead pattern portion At are formed (inner layer pattern formation step).

A multilayer portion (layered circuit pattern portion Acs/outer layer circuit pattern portion Ace (see FIG. 19)) is configured by, in a subsequent step, layering an outer layer circuit pattern (conductor layer 122) on the inner layer circuit pattern portion Acf.

The lead pattern 112t is a lead pattern (flexible portion employed as a cable) for making an external connection, and is extended from the inner layer circuit pattern 112c (the inner layer circuit pattern portion Acf). Formed at the tip of the lead pattern 112t is an exposed portion 112tt that acts as a terminal portion/land portion. Also, surface treatment such as metal plating or the like is performed on the exposed portion 112tt in a subsequent step, so that the exposed portion 112tt functions as a connection terminal that is connected to outside. That is, the exposed portion 112tt is a portion drawn out as a connection terminal of the lead pattern portion At of the completed multilayer printed wiring board.

A discarded plate portion Ah that is ultimately cut is disposed around the circumference of the inner layer circuit pattern portion Acf (layered circuit pattern portion Acs) and the lead pattern portion At.

FIG. 18 is a cross-sectional view that shows a state in which an insulating protective film has been formed on the inner layer base material shown in FIG. 17.

After an inner layer pattern formation step, a coverlay 114 that serves as an insulating protective film is fastened to conductor layer portions other than the exposed portion 112tt (the inner layer circuit pattern 112c, the inner layer circuit pattern 113c, and the lead pattern 112t).

Ordinarily, the same material as the insulating resin film of the inner layer insulating base material 111, with the same thickness, is used as the coverlay 114. The coverlay 114 includes a coverlay base material 114a and a coverlay adhesive layer 114b. Also, when necessary, a surface treatment such as metal plating or the like is performed on the exposed portion 112tt (terminal/land portion).

FIG. 19 is a cross-sectional view that shows a state in which the outer layer base material has been layered on the inner layer base material shown in FIG. 18. FIG. 20 is a plan view of FIG. 19. In FIG. 20, for the sake of a more legible drawing, circuit patterns, resists, holes, and the like are not shown.

Next, an outer layer base material 120, and an interlayer adhesive layer 125 that fastens the outer layer base material 120 to the inner layer base material 110, are prepared. The outer layer base material 120 is configured with an outer layer insulating base material 121 that serves as an outer layer core, and a conductor layer 122 formed on the surface of the outer layer insulating base material 121.

Employed as the outer layer base material 120 is, for example, a single-sided flexible wiring board material that is ordinarily commercially available. In this material, copper foil (the conductor layer 122) is layered on an insulating material (the outer layer insulating base material 121) of glass epoxy or polyimide.

The interlayer adhesive layer 125 is layered on a face where the outer layer base material 120 faces the inner layer base material 110, and with a layering press or the like, the outer layer base material 120 is layered and fastened to the inner layer base material 110 (base material layering step; FIG. 19).

A portion that corresponds to the layered circuit pattern portion Acs in the outer layer base material 120 layered on the inner layer base material 110 becomes the outer layer circuit pattern portion Ace with the formation of an outer layer circuit pattern (not shown) by patterning of the conductor layer 122 (outer layer pattern formation step).

After the base material layering step, applying a multilayer printed wiring board manufacturing method that includes through-hole processing, panel plating, outer layer circuit pattern formation, solder resist formation, silk printing, and surface treatment such as plating or rust-proofing treatment, steps advance until immediately before outer shape processing.

In the multilayer printed wiring board in a completed state, it is necessary that the lead pattern portion At (flexible portion) is exposed to the outside. That is, it is necessary that a portion that corresponds to the lead pattern portion At of the outer layer base material 120 layered on the inner layer base material 110 in the base material layering step is removed prior to completion of the multilayer printed wiring board. Also, the lead pattern portion At has a border position BP of a border with the multilayer portion (layered circuit pattern portion Acs/outer layer circuit pattern portion Ace/outer layer circuit pattern portion Ace). Note that the multilayer portion is harder than the flexible portion, because the inner layer base material 110 and the outer layer base material 120 have been layered.

Accordingly, in order to facilitate removal of the outer layer base material 120 in a region that corresponds to the lead pattern portion At, a separation slit 120g is formed in advance prior to layering at a portion that corresponds to the border position BP of the outer layer base material 120, and the interlayer adhesive layer 125 is removed in advance in the region that corresponds to the lead pattern portion At.

That is, the inner layer base material 110 is not fastened to the outer layer base material 120 in the portion that becomes the flexible portion due to formation of the separation slit 120g and removal of the interlayer adhesive layer 125 in the region corresponding to the lead pattern portion At. Accordingly, by performing outer shape processing (outer circumferential edge formation) of the flexible portion/multilayer portion (multilayer printed wiring board) in an outer circumferential edge formation step, which is a subsequent step, it is possible to remove the outer layer base material 120 in a portion that corresponds to the lead pattern portion At.

As shown in FIG. 20, at cutting line DL, outer shape processing is performed (outer circumferential edge formation step). The separation slit 120g extends slightly to the outside of the cutting line DL. Thus, when outer shape processing is performed by perforation with a metal die or the like corresponding to the cutting line DL, the outer layer base material 120 is separated into two portions at the separation slit 120g, the two portions being a multilayer portion side and a flexible portion side.

The outer layer base material 120 (outer layer circuit pattern portion Ace) of the multilayer portion (layered circuit pattern portion Acs) side is fastened to the inner layer base material 110 (inner layer circuit pattern portion Acf) with adhesive, while the outer layer base material 120 of the flexible portion (lead pattern portion At) is only closely fitted physically with pressure and heat in a step during substrate layering because there is no interlayer adhesive layer 125. The outer layer base material 120 superimposed on the flexible portion (lead pattern portion At) is peeled away with a jig or by hand, and thus the multilayer printed wiring board is completed.

Methods for layering outer layer base material on inner layer base material after slit is formed in advance in order to separate unnecessary outer layer base material are disclosed in, for example, JP H7-106765A, JP H9-331153A, JP 2003-31950A, and JP 2006-210873A.

FIG. 21 is a cross-sectional view that shows a state in which an outer layer circuit pattern has been formed by layering the outer layer base material on the inner layer base material, in a method for manufacturing a multilayer printed wiring board according to Conventional Example 2.

Other than Conventional Example 1, a method cited as Conventional Example 2 has been proposed in which a slit is not formed in advance in the outer layer base material. For example, in such a method, after layering the outer layer base material, only the outer layer base material is cut with a laser, or the outer layer base material is mechanically peeled away. When the outer layer base material is mechanically peeled away, the cutting position is likely to become uncertain, so it is known to perform some measure such that the outer layer base material is peeled away at a desired location. Specifically, processing is performed up to the base material layering step shown in FIG. 19 with the same procedure as in Conventional Example 1. Unlike in the case of Conventional Example 1, in Conventional Example 2a separation slit 120g is not formed.

In Conventional Example 2, as a means of assisting cutting of outer layer base material 120, when a conductor layer 122 is patterned to form an outer layer circuit pattern 122c, thus configuring an outer layer circuit pattern portion Ace (outer layer pattern formation step), the conductor layer 122 is patterned so that two border delineating patterns 122cg are formed that sandwich a border position BP. It is also possible to have only any single border delineating pattern 122cg. After the outer layer pattern formation step, processing such as solder resist formation, silk printing, and the like are performed.

FIG. 22 is a plan view that shows a state in which a cutting slit has been formed after configuring the outer layer pattern portion in FIG. 21. In FIG. 22, for the sake of a more legible drawing, circuit patterns, resists, holes, and the like are not shown.

After the outer layer pattern formation step, a cutting slit 120f is formed by center hole processing performed at the circumference of the flexible portion, except for border position BP of the lead pattern portion At (flexible portion) and the multilayer portion (layered circuit pattern portion Acs/inner layer circuit pattern portion Acf/outer layer circuit pattern portion Ace). Due to formation of the cutting slit 120f, the cutting end portion 122ff (angle portion and end portion) of the outer layer base material 120 corresponding to the end position of the lead pattern portion At is exposed.

The outer layer base material 120 covering the lead pattern portion At is composed of material that is comparatively fragile and can be peeled away, so bending or peeling away of the outer layer base material 120 at the border position BP is possible. Accordingly, by peeling away the outer layer base material 120 from the exposed cutting end portion 122ff, it is possible to remove the outer layer base material 120 that corresponds to the lead pattern portion At.

Also, the border delineating pattern 122cg acts as a guide when peeling the outer layer base material 120, and acts such that the outer layer base material 120 is not peeled away at an unintended portion.

After removing the excess portion of the outer layer base material 120, outer shape processing is performed on the flexible portion and the multilayer portion, and thus the multilayer printed wiring board is completed.

Other than Conventional Example 2, methods of removing outer layer base material of a flexible portion have been proposed. Among these are methods employing half-punching and methods for performing half-groove processing from inside (for example, see JP H5-90756A), methods for cutting from outside during final outer shape processing (for example, see JP H4-34993A), simple methods in which an adhesive layer is not applied on a flexible portion (for example, see JP H6-216531A, and JP H9-74252A).

Also, methods have been proposed in which, when outer layer base material is comparatively thin, a portion corresponding to the flexible portion is cut out and removed in advance (for example, see JP H6-216537A, JP H8-148835A, and JP 2006-186178A).

Methods have been proposed in which, when outer layer base material is comparatively thick, because of the problem that layer fastening cannot be performed uniformly due to a difference in the thickness of a flexible portion and a multilayer portion, a member that has been cut out and removed or another member is temporarily returned to a hole where the member was removed, and then the member is removed again after layering, or a mold releasing member is sandwiched, or a material having mold releasing properties is used, or the like (for example, see JP H3-290990A, JP H7-50456A, JP H6-216533A, and JP H6-252552A).

Further, methods have been proposed such as sandwiching a double-sided mold releasing member or a self-peeling adhesive between the flexible portion and the outer layer base material (for example, see JP H7-135393A.

As is clear from the conventional examples, how to remove outer layer base material that is superimposed on a flexible portion, i.e., how to insure that the outer layer base material and the inner layer base material that constitutes the flexible portion are not fastened, is the most important technological point in the manufacturing process for a multilayer printed wiring board of the flex-rigid type.

As disclosed in Conventional Examples 1 and 2, a technique is most widespread in which an interlayer adhesive layer is perforated in advance by die processing or the like. However, with this technique, it is unexpectedly difficult to properly perform die processing without soiling an adhesive face, and there are problems (1) to (4) as given below.

(1) The adhesive face is tacky, and has not yet hardened, so trash or dust easily attach to the adhesive face.
(2) When processing is performed with a die, the adhesive face is easily soiled by oil or the like from hands or machinery.
(3) Even if the adhesive face has been protected with mold separation paper or the like, when that paper is peeled away, it is likely that a peel-away electric charge will occur, or that soiled matter of the mold separation paper will move.
(4) It is difficult to perform layering with the position of an adhesive sheet that has undergone hole processing properly matched to that of the inner layer base material.

In other words, there are the problems that after the base material layering step, the likelihood that adhesive properties will decrease, and the likelihood that defects due to debris will occur, are high, and the precision of the position of the flexible portion is reduced.

Also, there is the problem that when slit processing has been performed on the outer layer base material in advance, or when hole processing has been performed, incontinuity occurs in the total thickness at the border of the multilayer portion and the flexible portion, and when fastening a layer, because layering pressure is uneven, adhesive flows to the flexible portion, for which pressure is lower than for the multilayer pressure, and which has a gap, so that total thickness of the multilayer portion near the flexible portion becomes thinner in a sloped manner, or there is the problem that the adhesive protrudes to the region of the flexible portion, so the outer layer base material is fastened at an unintended portion of the flexible portion and thus the outer layer base material cannot be peeled away. In addition to the problems above, there is also the problem that due to the adhesive protruding in the vicinity of the border of the flexible portion and the multilayer portion, there is a decrease in quality.

Further, an edge of the hole portion (slit portion) functions as a knife during layering, damaging the flexible portion at the border position of the flexible portion and the multilayer portion, and so a circumstance occurs in which the bending properties of the completed multilayer printed wiring board at the flexible portion, in particular anti-flexibility of the flexible portion at the border position of the flexible portion and the multilayer portion, are decreased.

Also, there are the problems that when a slit is formed in advance in the outer layer base material, or when the outer layer base material that corresponds to the flexible portion is removed in advance, in a de-smearing processing performed during through hole or via hole formation, via a slit or a region where the outer layer base material has been removed, inner layer base material in an exposed state or insulating resin base material of the flexible portion is damaged, so that there is a marked reduction in insulation properties, interlayer adhesive strength, flexibility resistance, friction resistance, and the like. In order to avoid these problems, a measure is necessary such as producing, in advance, a metal film that is resistant to de-smearing treatment (see JP 2003-115665A).

Also in the case of a method in which a mold releasing member is sandwiched, much time and effort is required to dispose the mold releasing member at an appropriate position, and it is very difficult to perform control such that the mold releasing member is not displaced during layering, so stable production is difficult.

### SUMMARY OF THE INVENTION

The present invention was made in view of such circumstances, and it is an object thereof to provide a method for manufacturing a multilayer printed wiring board provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method being such that by forming a lead portion corresponding resin film that corresponds to the range of the lead pattern portion on the interlayer adhesive layer to prevent the interlayer adhesive layer from adhering to the inner layer base material, the inner layer base material and the outer layer base material are layered and fastened with uniform pressure, and so the lead portion corresponding resin film, the interlayer adhesive layer, and the outer layer base material can be easily and precisely removed from the lead pattern portion.

The method for manufacturing a multilayer printed wiring board according to the present invention is a method for manufacturing a multilayer printed wiring board provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method being provided with an inner layer pattern formation step of pattering a conductor layer of the inner layer base material to form the inner layer circuit pattern portion and the lead pattern portion, a dummy pattern formation step of forming a metal layer dummy pattern on the outer layer base material, the dummy pattern expressing the range of the lead pattern portion, an interlayer adhesive layer formation step of forming an interlayer adhesive layer on the surface of the outer layer base material where the dummy pattern has been formed, a resin film application step of applying, corresponding to the dummy pattern, a lead portion corresponding resin film to the interlayer adhesive layer, the lead portion corresponding resin film being formed corresponding to the range of the lead pattern portion, a base material layering step of layering the outer layer base material on the inner layer base material via the interlayer adhesive layer, with the position of the lead portion corresponding resin film matched to the position of the lead pattern portion, an outer layer pattern formation step of forming the outer layer circuit pattern portion corresponding to the inner layer circuit pattern portion by patterning the conductor layer of the outer layer base material layered on the inner layer base material, and an outer layer base material removal step of separating the lead portion corresponding resin film from the inner layer base material to remove the interlayer adhesive layer and the outer layer base material layered on the lead portion corresponding resin film.

With this configuration, a height difference due to the thickness of the lead portion corresponding resin film is absorbed, so that it is possible to layer the outer layer base material and the inner layer base material by applying pressure uniformly, in a state in which the lead pattern portion and the outer layer base material (and the interlayer adhesive layer) are not fastened. That is, even when the interlayer adhesive layer and the outer layer base material are not processed in advance, it is possible to layer the inner layer base material and the outer layer base material without adhering the interlayer adhesive layer to the lead pattern portion, so it is possible to easily and precisely separate the lead portion corresponding resin film, the interlayer adhesive layer, and the outer layer base material from the inner layer base material. Accordingly, it is possible to form a precisely positioned lead pattern portion with distortion by outer layer base material or affecting of the interlayer adhesive layer to the lead pattern portion in the base material layering step or the outer layer base material removal step eliminated, and so by eliminating processing defects, the cutting face at the border between the layered circuit pattern portion and the lead pattern portion can be clean and distortion free, so it is possible to manufacture, with good productivity, a multilayer printed wiring board having a lead pattern portion with high precision and high bendability.

In the above configuration, a configuration may be adopted in which the outer layer base material is constituted from a double-sided wiring base material, and a conductor layer on one side is etched to form the dummy pattern.

With this configuration, it is possible to very easily and productively form a dummy pattern.

Also, in the above configuration, a configuration may be adopted in which the dummy pattern has a pattern that corresponds to a border of the layered circuit pattern portion and the lead pattern portion.

With this configuration, it is possible to easily and precisely delineate and form the border of the layered circuit pattern portion and the lead pattern portion.

Also, in the above configuration, a configuration may be adopted in which the method for manufacturing a multilayer printed wiring board is provided with, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

With this configuration, it is possible to expose the lead portion corresponding resin film to the outer circumferential edge, so it is possible to very easily remove the outer layer base material from the inner layer base material (lead pattern portion).

Further, in the above configuration, a configuration may be adopted in which the lead portion corresponding resin film is constituted from polyimide resin, and is provided with a surface that can be bonded to the interlayer adhesive layer.

With this configuration, it is possible to easily and precisely apply the lead portion corresponding resin film to the interlayer adhesive layer.

Also, in the above configuration, the lead portion corresponding resin film may be polyimide film in which a heat sensitive adhesive has been applied to a surface that faces the interlayer adhesive layer.

With this configuration, adhesiveness of the lead portion corresponding resin film can easily be insured, and it is possible to make pressure applied during layering uniform, so it is possible to form the lead pattern portion with greater precision.

Also, in the above configuration, the lead portion corresponding resin film may be formed extended to the outside of the outer circumferential edge of the lead pattern portion.

With this configuration, because it is possible to reliably expose the lead portion corresponding resin film at the outer circumferential edge formed in the outer circumferential edge formation step, it is possible to very easily and precisely separate the lead portion corresponding resin film, the interlayer adhesive layer, and the outer layer base material from the inner layer base material.

The method for manufacturing a multilayer printed wiring board according to the present invention is a method for manufacturing a multilayer printed wiring board provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method including an inner layer pattern formation step of pattering a conductor layer of the inner layer base material to form the inner layer circuit pattern portion and the lead pattern portion, an interlayer adhesive layer formation step of forming an interlayer adhesive layer on the outer layer base material, a resin film temporary fastening step of temporarily fastening a temporary fastening resin film for forming a lead portion corresponding resin film on the surface of the interlayer adhesive layer, a resin film cutting step of cutting the temporary fastening resin film along the range of the lead pattern portion, a resin film peeling step of peeling away the temporary fastening resin film to leave the temporary fastening resin film that corresponds to the range of the lead pattern portion as the lead portion corresponding resin film, a base material layering step of layering the outer layer base material on the inner layer base material via the interlayer adhesive layer, with the position of the lead portion corresponding resin film matched to the position of the lead pattern portion, an outer layer pattern formation step of pattering a conductor layer of the outer layer base material layered on the inner layer base material to form the outer layer circuit pattern portion corresponding to the inner layer circuit pattern portion, and an outer layer base material removal step of separating the lead portion corresponding resin film from the inner layer base material to remove the interlayer adhesive layer and the outer layer base material layered on the lead portion corresponding resin film.

With this configuration, a height difference due to the thickness of the lead portion corresponding resin film is absorbed, so that it is possible to layer the outer layer base material and the inner layer base material by applying pressure uniformly, in a state in which the lead pattern portion and the outer layer base material (and the interlayer adhesive layer) are not fastened. That is, even when the interlayer adhesive layer and the outer layer base material are not processed in advance, it is possible to layer the inner layer base material and the outer layer base material without adhering the interlayer adhesive layer to the lead pattern portion, so it is possible to easily and precisely separate the lead portion corresponding resin film, the interlayer adhesive layer, and the outer layer base material from the inner layer base material. Accordingly, it is possible to form a precisely positioned lead pattern portion with distortion by the outer layer base material or affecting of the interlayer adhesive layer to the lead pattern portion in the base material layering step or the outer layer base material removal step eliminated, and so by eliminating processing defects, the cutting face at the border between the layered circuit pattern portion and the lead pattern portion can be clean and distortion free, so it is possible to manufacture, with good productivity, a multilayer printed wiring board having a lead pattern portion with high precision and high bendability.

In this configuration, a configuration may be adopted in which in the resin film cutting step, a cut-in is formed up to the outer layer base material by the cutting of the temporary fastening resin film.

With this configuration, it is possible to very easily, precisely, and productively perform removal of the outer layer base material in the outer layer base material removal step.

Also, in this configuration, a configuration may be adopted in which is provided, before the outer layer base material removal step, an outer circumference edge formation step of cutting the layered circuit pattern portion configured by the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

With this configuration, it is possible to expose the lead portion corresponding resin film to the outer circumferential edge, so it is possible to very easily remove the outer layer base material from the inner layer base material (lead pattern portion).

Also, in this configuration, a configuration may be adopted in which the temporary fastening resin film is constituted from polyimide resin, and is provided with a surface that can be bonded to the interlayer adhesive layer.

With this configuration, it is possible to easily and precisely apply the lead portion corresponding resin film to the interlayer adhesive layer.

Also, in the method for manufacturing a multilayer printed wiring board according to the present invention, the temporary fastening resin film is a polyimide film in which a heat sensitive adhesive has been applied to a surface that faces the interlayer adhesive layer.

With this configuration, adhesiveness of the lead portion corresponding resin film can easily be insured, and it is possible to make pressure applied during layering uniform, so it is possible to form the lead pattern portion with greater precision.

Also, in the above configuration, the lead portion corresponding resin film may be formed extended to the outside of the outer circumferential edge of the lead pattern portion.

With this configuration, because it is possible to reliably expose the lead portion corresponding resin film at the outer circumferential edge formed in the outer circumferential edge formation step, it is possible to very easily and precisely separate the lead portion corresponding resin film, the interlayer adhesive layer, and the outer layer base material from the inner layer base material.

The method for manufacturing a multilayer printed wiring board according to the present invention is a method for manufacturing a multilayer printed wiring board provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method including an inner layer pattern formation step of pattering a conductor layer of the inner layer base material to form the inner layer circuit pattern portion and the lead pattern portion, an interlayer adhesive layer formation step of forming an interlayer adhesive layer on the outer layer base material, a resin film formation step of forming a lead portion corresponding resin film that corresponds to the lead pattern portion on the surface of the interlayer adhesive layer, a base material layering step of layering the outer layer base material on the inner layer base material via the interlayer adhesive layer, with the position of the lead portion corresponding resin film matched to the position of the lead pattern portion, an outer layer pattern formation step of pattering a conductor layer of the outer layer base material layered on the inner layer base material to form the outer layer circuit pattern portion corresponding to the inner layer circuit pattern portion, and an outer layer base material removal step of separating the lead portion corresponding resin film from the inner layer base material to remove the interlayer adhesive layer and the outer layer base material layered on the lead portion corresponding resin film.

With this configuration, a height difference due to the thickness of the lead portion corresponding resin film is absorbed, so that it is possible to layer the outer layer base material and the inner layer base material by applying pressure uniformly, in a state in which the lead pattern portion and the outer layer base material (and the interlayer adhesive layer) are not affixed. That is, even when the interlayer adhesive layer and the outer layer base material are not processed in advance, it is possible to layer the inner layer base material and the outer layer base material without adhering the interlayer adhesive layer to the lead pattern portion, so it is possible to easily and precisely separate the lead portion corresponding resin film, the interlayer adhesive layer, and the outer layer base material from the inner layer base material. Accordingly, it is possible to form a precisely positioned lead pattern portion with distortion by the outer layer base material or affecting of the interlayer adhesive layer to the lead pattern portion in the base material layering step or the outer layer base material removal step eliminated, and so by eliminating processing defects, the cutting face at the border between the layered circuit pattern portion and the lead pattern portion can be clean and distortion free, so it is possible to manufacture, with good productivity, a multilayer printed wiring board having a lead pattern portion with high precision and high bendability.

With the method for manufacturing a multilayer printed wiring board according to the present invention, it is not necessary to perform processing on the outer layer base material and the interlayer adhesive layer as with a conventional method, so processing steps can be simplified, and height differences due to processing do not occur, so an effect is obtained that it is possible to prevent processing defects such as damage to the lead pattern portion or protrusion of the adhesive from the interlayer adhesive layer.

### BRIEF DESCRIPTION OF THE DRAWINGS

FIG. 1 is a cross-sectional view that shows the configuration of an inner layer base material applied in a method for manufacturing a multilayer printed wiring board according to Embodiment 1 of the present invention.

FIG. 2 is a cross-sectional view that shows a state in which an inner layer circuit pattern portion and a lead pattern portion have been formed in the inner layer base material shown in FIG. 1.

FIG. 3 is a cross-sectional view that shows a state in which an insulating protective film has been formed on the inner layer base material shown in FIG. 2.

FIG. 4 is a cross-sectional view of an outer layer base material prepared for layering on the inner layer base material shown in FIG. 3.

FIG. 5 is a cross-sectional view that shows an arrangement when a lead portion corresponding resin film is applied to the outer layer base material shown in FIG. 4 and layered on the inner layer base material.

FIG. 6 is a plan view that conceptually shows a layering relationship of the inner layer base material and the outer layer base material shown in FIG. 5, viewed from above.

FIG. 7 is a cross-sectional view that shows a state in which the inner layer base material and the outer layer base material shown in FIGS. 5 and 6 have been layered.

FIG. 8 is a cross-sectional view that shows a state in which a layered circuit pattern portion has been configured by forming an outer layer circuit pattern on the outer layer base material layered on the inner layer base material in FIG. 7.

FIG. 9 is a cross-sectional view that shows a state in which a multilayer printed wiring board is completed by forming outer circumferential edges of the layered circuit pattern portion and the lead pattern portion in FIG. 8, and then removing the outer layer base material that corresponds to the lead pattern portion from the inner layer base material.

FIG. 10 is a cross-sectional view of a multilayer printed wiring board obtained by layering an interlayer adhesive layer and a temporary fastening resin film to the outer layer base material prepared for layering on the inner layer base material applied in a method for manufacturing a multilayer printed wiring board according to Embodiment 2 of the present invention.

FIG. 11 is a cross-sectional view that shows a state in which the lead portion corresponding resin film has been delineated by cutting the temporary fastening resin film shown in FIG. 10.

FIG. 12 is a cross-sectional view that shows a state in which the lead portion corresponding resin film has been formed by peeling away the temporary fastening resin film shown in FIG. 11.

FIG. 13 is a cross-sectional view that shows a state in which the lead portion corresponding resin film shown in FIG. 12 has been applied and the inner layer base material and the outer layer base material have been layered.

FIG. 14 is a cross-sectional view of a multilayer printed wiring board obtained by layering the inner layer base material and the outer layer base material, employing the lead portion corresponding resin film according to Embodiment 2, in a method for manufacturing a multilayer printed wiring board according to Embodiment 3 of the present invention.

FIG. 15 is a cross-sectional view that shows the configuration of an inner layer base material applied in a method for manufacturing a multilayer printed wiring board according to Conventional Example 1.

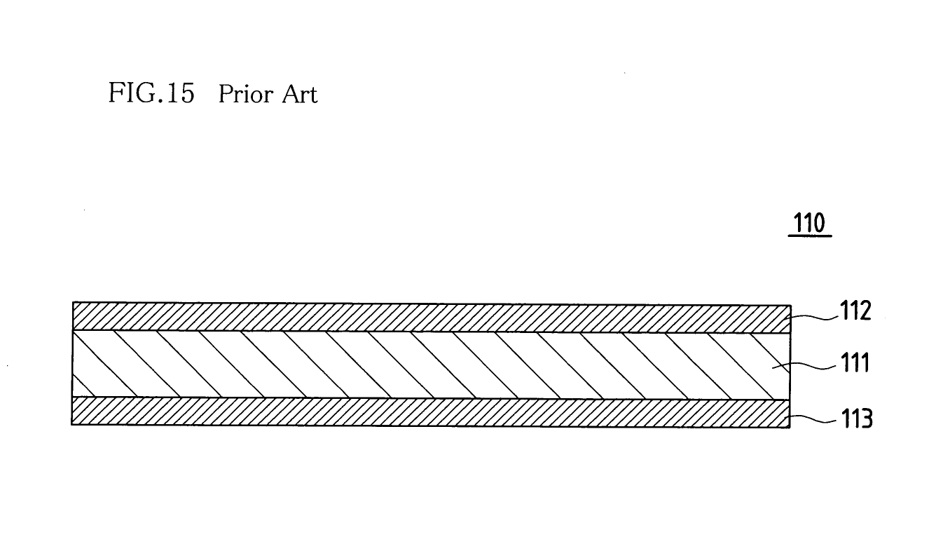

FIG. 16 is a cross-sectional view that shows a state in which a resist mask has been formed in order to form the inner layer circuit pattern portion and the lead pattern portion in the inner layer base material shown in FIG. 15.

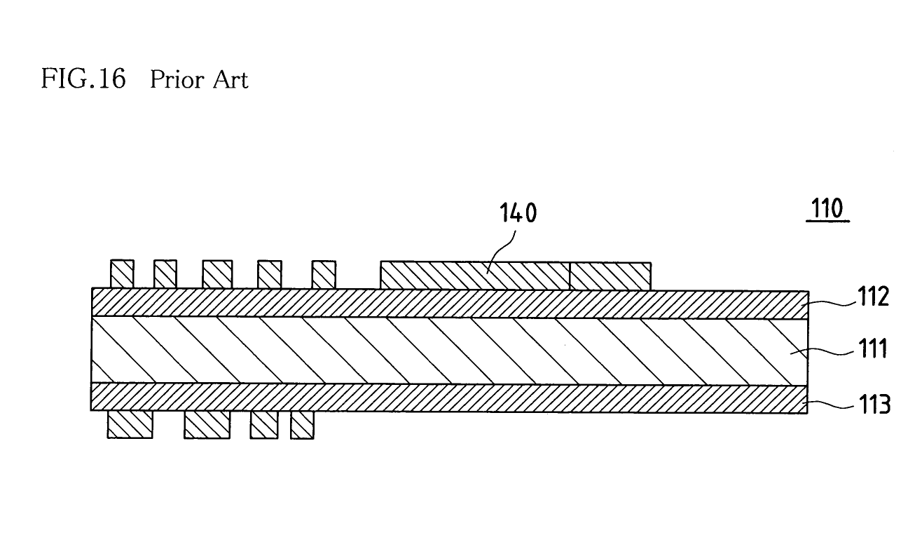

FIG. 17 is a cross-sectional view that shows a state in which an inner layer circuit pattern portion and a lead pattern portion have been formed in the inner layer base material, employing the resist mask shown in FIG. 16.

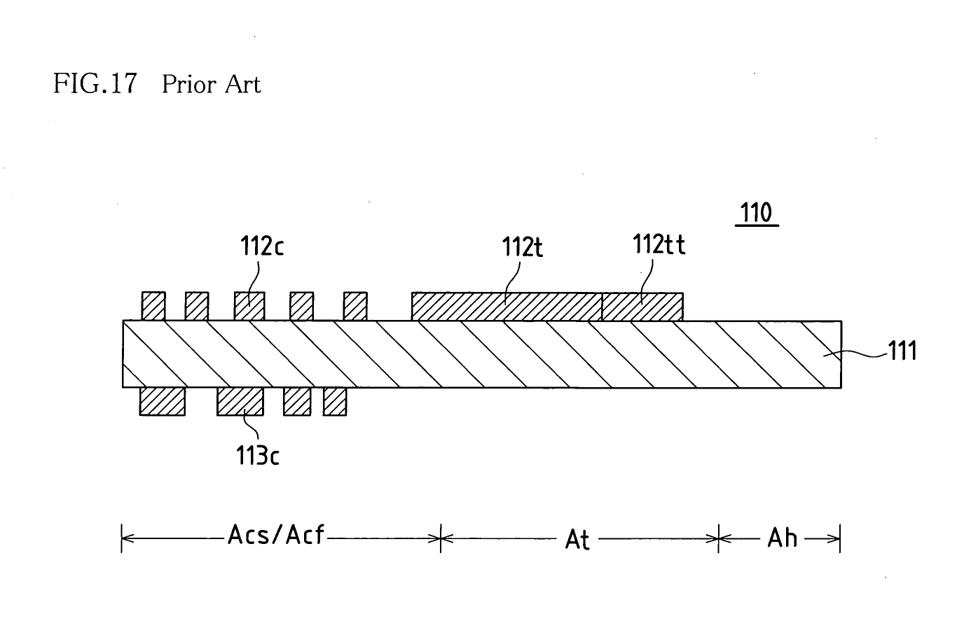

FIG. 18 is a cross-sectional view that shows a state in which an insulating protective film has been formed on the inner layer base material shown in FIG. 17.

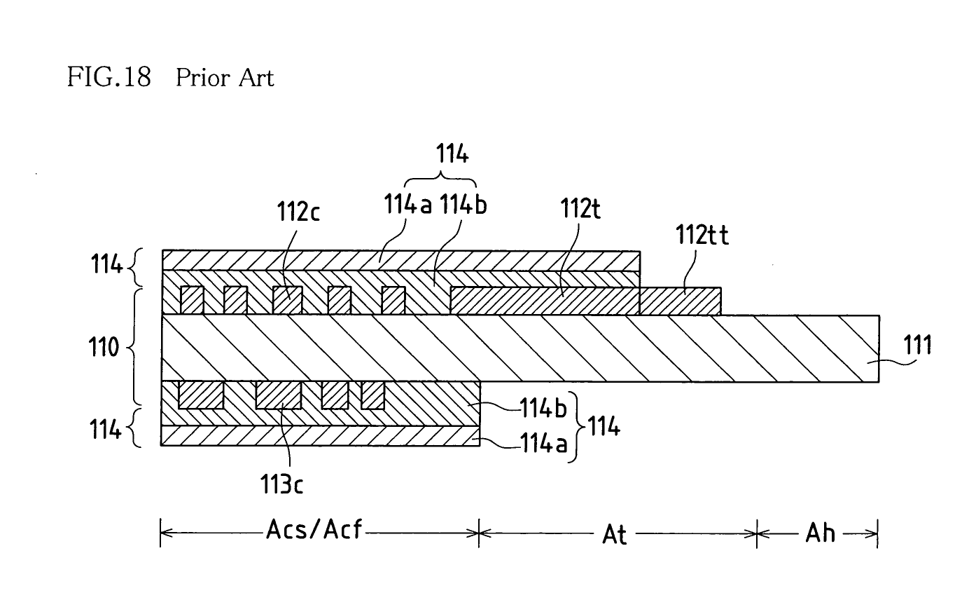

FIG. 19 is a cross-sectional view that shows a state in which the outer layer base material has been layered on the inner layer base material shown in FIG. 18.

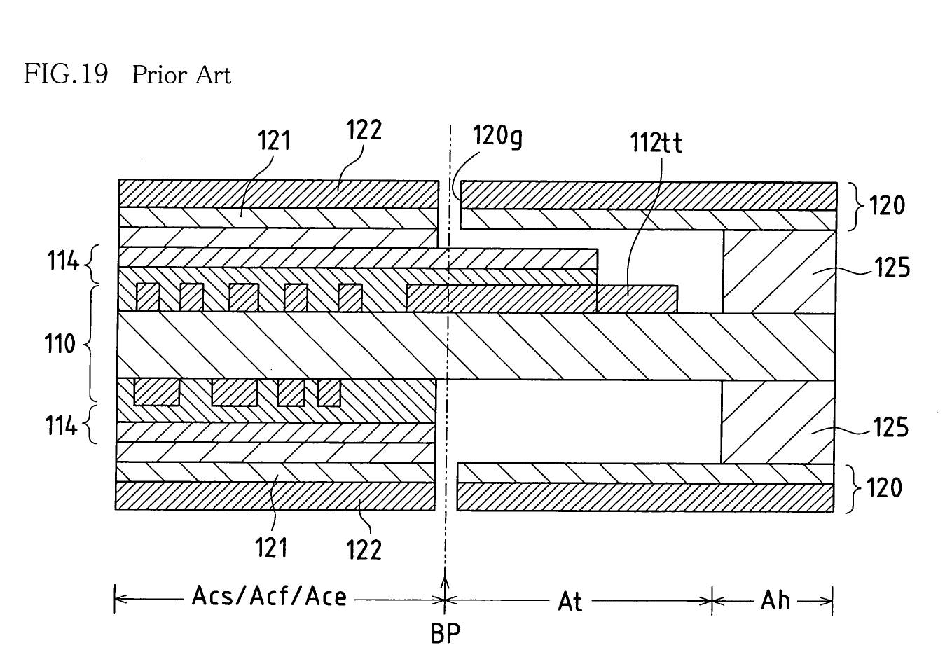

FIG. 20 is a plan view of FIG. 19.

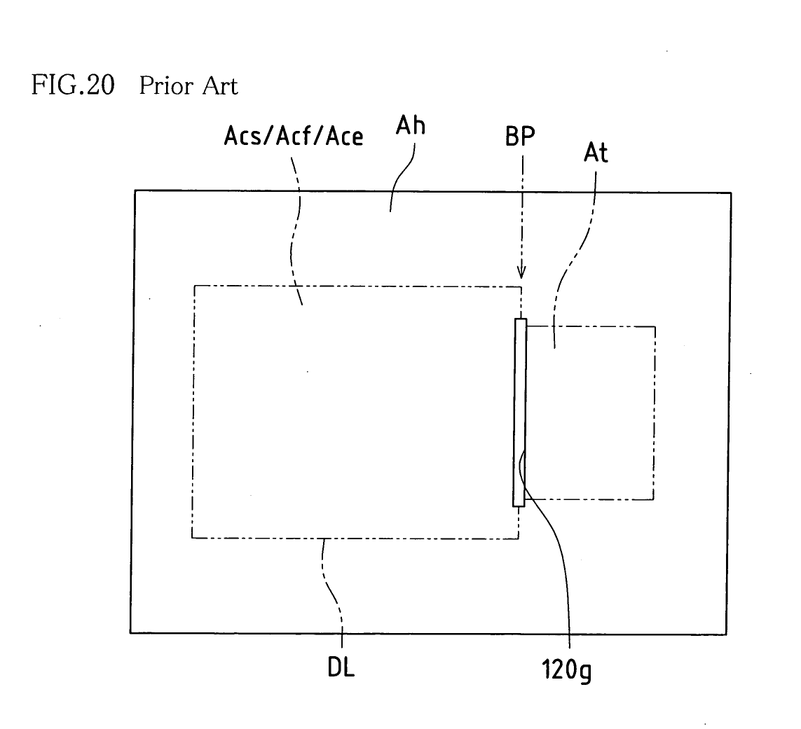

FIG. 21 is a cross-sectional view that shows a state in which an outer layer circuit pattern has been formed by layering the outer layer base material on the inner layer base material, in a method for manufacturing a multilayer printed wiring board according to Conventional Example 2.

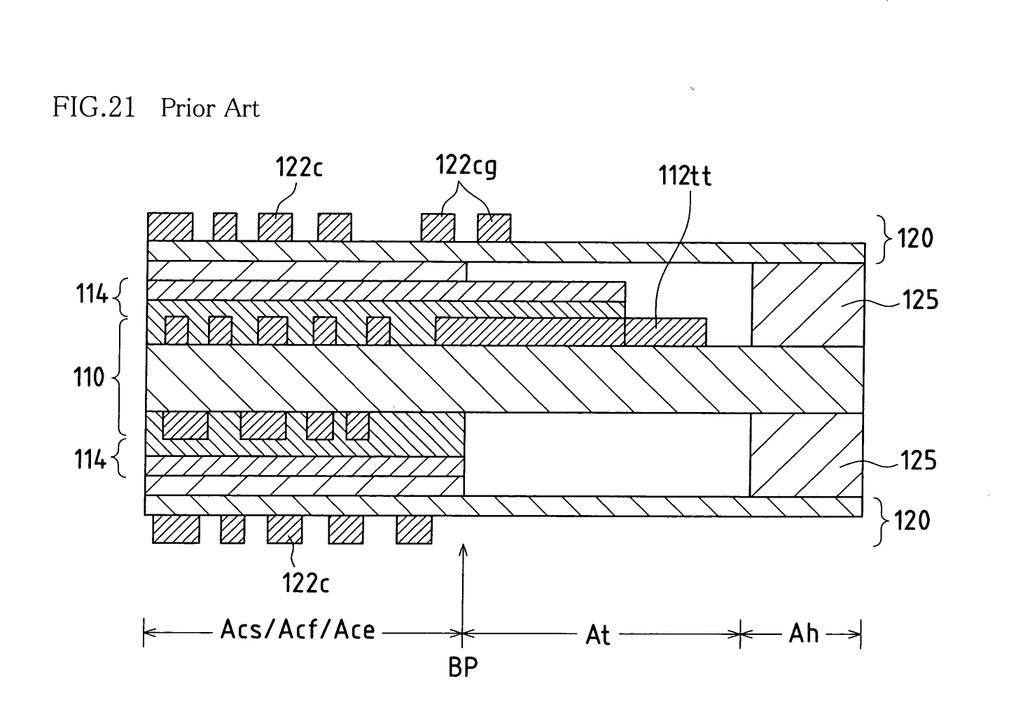

FIG. 22 is a plan view that shows a state in which a cutting slit has been formed after configuring the outer layer pattern portion in FIG. 21.

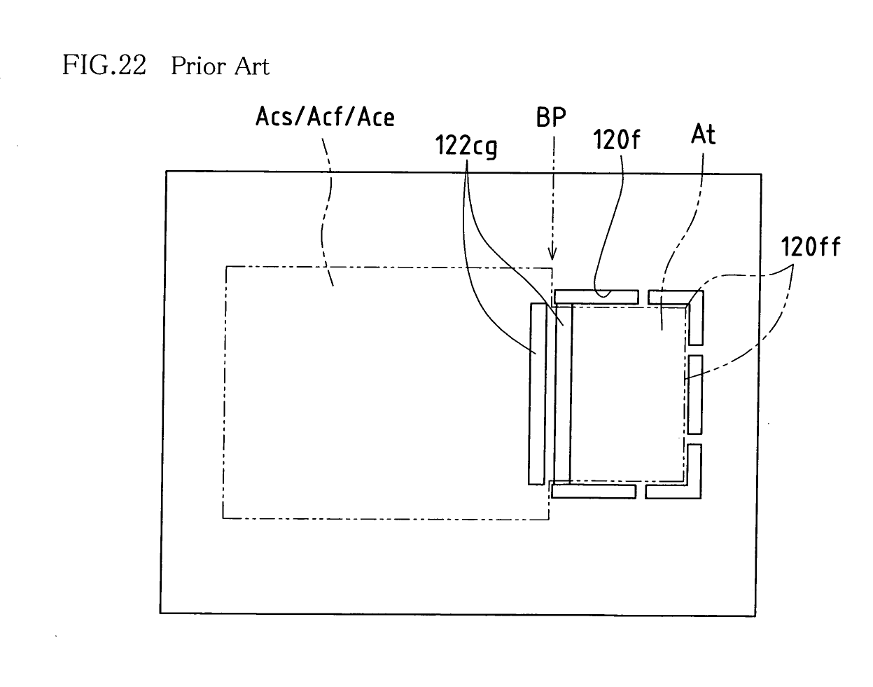

### DESCRIPTION OF THE PREFERRED EMBODIMENTS

Hereinafter, embodiments of the present invention will be described in detail with reference to the accompanying drawings. In order to simplify the description of the following embodiments, an example multilayer printed wiring board is disclosed with a configuration in which a flexible portion (a lead pattern portion) is a single-layer conductor layer, and a multilayer portion (a layered circuit pattern portion) is a four-layer conductor layer, but a layered circuit pattern portion Acs is not limited to being a four-layer conductor layer, and may be a three-layer conductor layer, or may have another multilayer configuration. Also, the following configurations are applicable in any form of multilayer printed wiring board, including a so-called built-up substrate according to a laser method, photo-via method, or the like.

### Embodiment 1

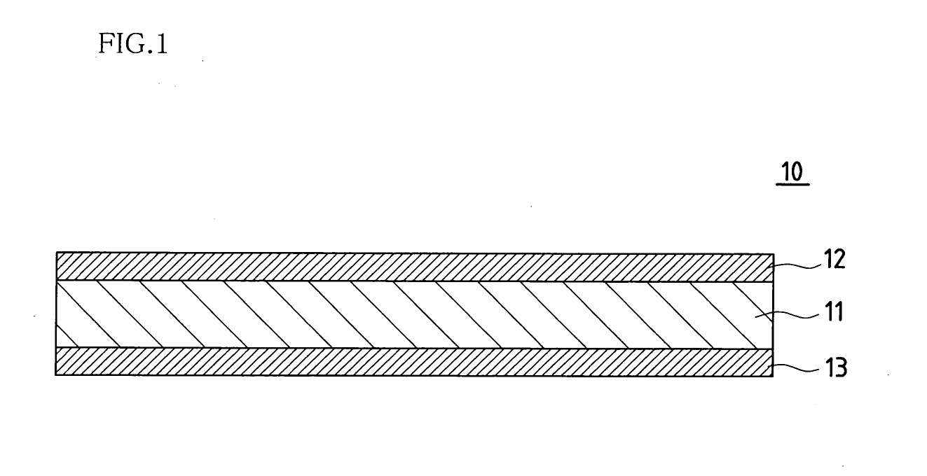

Following is a description of a method for manufacturing a multilayer printed wiring board according to Embodiment 1, with reference to FIGS. 1 to 9.

The present embodiment serves as an example of a multilayer printed wiring board (a so-called flying tail-type) with a form in which a flexible lead pattern portion is extended from approximately the middle in the thickness direction of the layered circuit pattern portion Acs where an inner layer circuit pattern portion and an outer layer circuit pattern portion have been layered.

FIG. 1 is a cross-sectional view that shows the configuration of an inner layer base material applied in a method for manufacturing a multilayer printed wiring board according to Embodiment 1 of the present invention.

An inner layer base material 10 is configured with a flexible inner layer insulating base material 11 that serves as an inner layer core, and conductor layers 12 and 13 formed on both faces of the inner layer insulating base material 11. The inner layer insulating base material 11, for example, is an insulating resin film such as a polyimide, polyether ketone, or crystal polymer. Also, the conductor layers 12 and 13 are obtained by layering, for example, a conductor metal (metal layer) such as copper foil on the surface of the inner layer insulating base material 11, via adhesive or without adhesive.

A double-sided flexible multilayer printed wiring board material that is ordinarily commercially available can be employed as the inner layer base material 10. In the present embodiment, for example, the material used has copper foil with a thickness of 12.5 μm to 25 μm layered and bonded to both faces of a polyimide film having a thickness of 25 μm. Accordingly, the inner layer base material 10 is configured to have flexibility as a whole. Also note that the material quality and thickness of the inner layer base material 10 are not directly related to the configuration of the present invention, and so they can be appropriately selected according to the necessary properties of the multilayer printed wiring board to be manufactured.

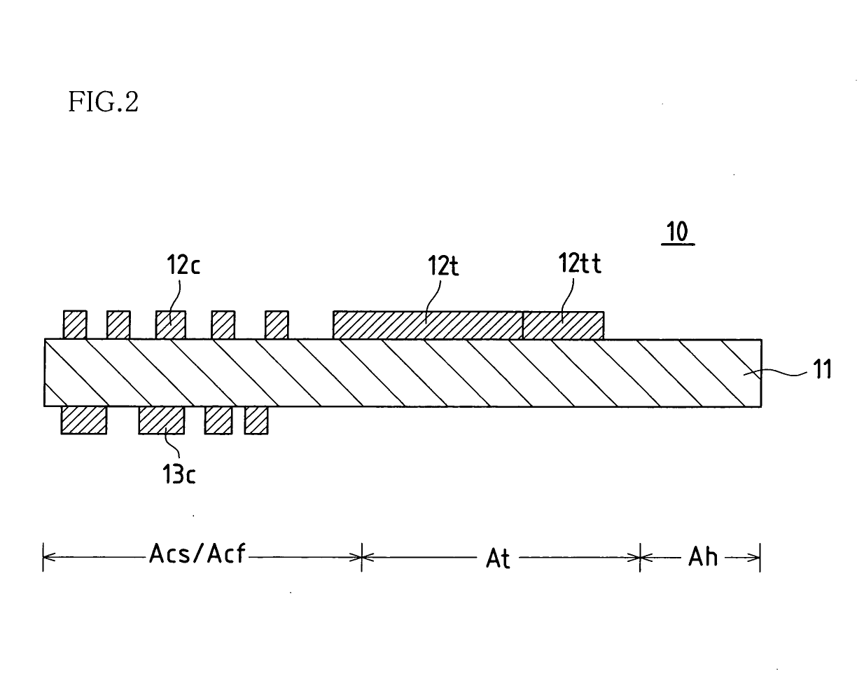

FIG. 2 is a cross-sectional view that shows a state in which an inner layer circuit pattern portion and a lead pattern portion have been formed in the inner layer base material shown in FIG. 1.

An etching resist is formed on the surface of the conductor layers 12 and 13 by employing a commonly-known circuit pattern formation method (such as a photolithography method), and by etching (patterning) the conductor layers 12 and 13 with an appropriate etching fluid (for example, such as cupric chloride or ferrous chloride), an inner layer circuit pattern 12c, an inner layer circuit pattern 13c, and a lead pattern 12t are formed.

The inner layer circuit pattern 12c and the inner layer circuit pattern 13c constitute an inner layer circuit pattern portion Acf The lead pattern 12t constitutes a lead pattern portion At extended from the inner layer circuit pattern portion Acf. That is, by patterning the conductor layers 12 and 13 of the inner layer base material 10, the inner layer circuit pattern portion Acf and the lead pattern portion At are formed (inner layer pattern formation step).

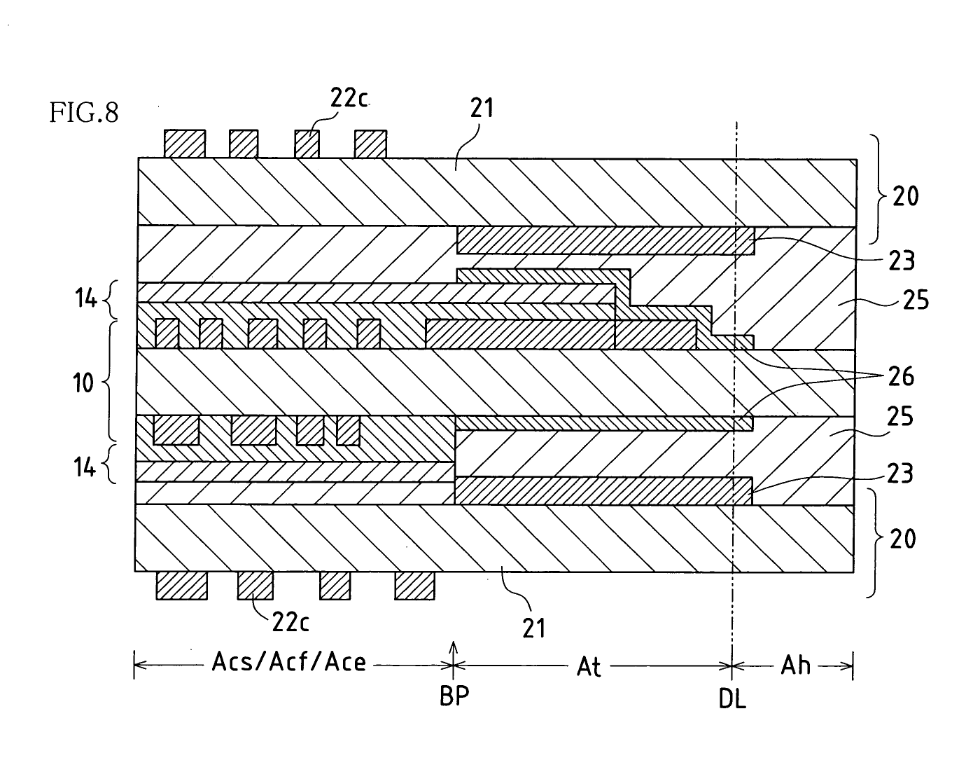

The inner layer circuit pattern portion Acf has a two-layer structure, but the inner layer circuit pattern portion Acf can also be configured with a single-layer structure of only the inner layer circuit pattern 12c. Also, a layered circuit pattern portion Acs/outer layer circuit pattern portion Ace (see FIG. 8) is configured by, in a subsequent step, layering an outer layer circuit pattern 22c on the inner layer circuit pattern portion Acf.

The lead pattern 12t is a lead pattern for making an external connection, and is extended from the inner layer circuit pattern 12c (the inner layer circuit pattern portion Acf). Formed at the tip of the lead pattern 12t is an exposed portion 12tt that acts as a terminal portion/land portion. Also, surface treatment such as metal plating or the like is performed on the exposed portion 12tt in a subsequent step, so that the exposed portion 12tt functions as a connection terminal that is connected to outside. That is, the exposed portion 12tt is a portion drawn out as a connection terminal of the lead pattern portion At of the completed multilayer printed wiring board.

In the present embodiment, the lead pattern portion At is configured having only a single layer of the lead pattern 12t, so the lead pattern extended from the inner layer circuit pattern 13c is not formed.

Also, when an inner via hole that connects the inner layer circuit pattern 12c and the inner layer circuit pattern 13c (or the outer layer circuit pattern 22c described below) to each other, in the same manner as a conventional method, it is possible to appropriately perform through hole processing, hole filling processing, or the like if necessary.

A discarded plate portion Ah that is ultimately cut away is disposed around the circumference of the inner layer circuit pattern portion Acf (layered circuit pattern portion Acs) and the lead pattern portion At.

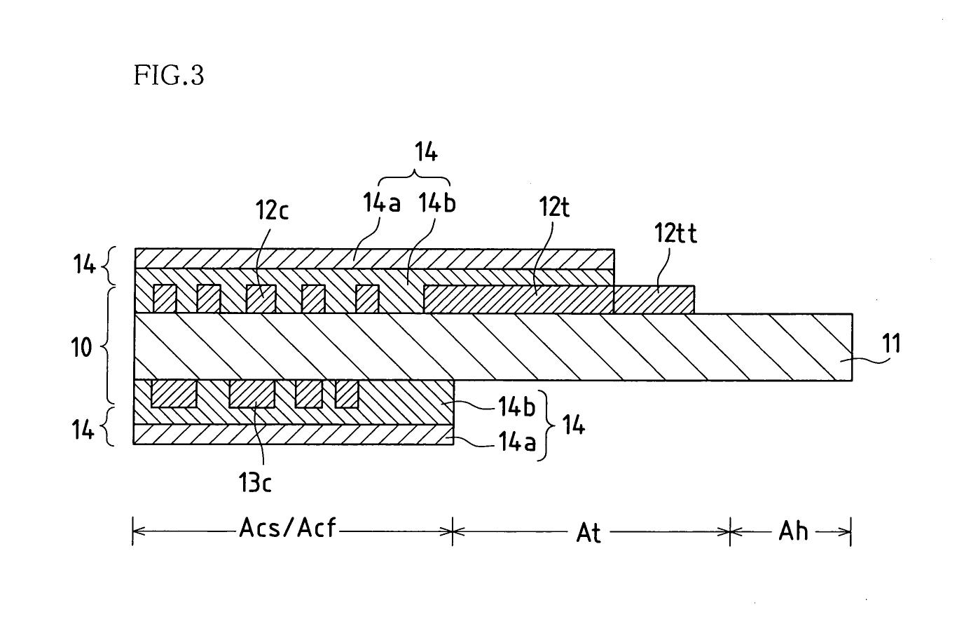

FIG. 3 is a cross-sectional view that shows a state in which an insulating protective film has been formed on the inner layer base material shown in FIG. 2.

After an inner layer pattern formation step, a coverlay 14 that serves as an insulating protective film is fastened to conductor layer portions other than the exposed portion 12tt (the inner layer circuit pattern 12c, the inner layer circuit pattern 13c, and the lead pattern 12t). It is desirable to employ the same material as the insulating resin film of the inner layer insulating base material 11, with the same thickness, is used as the coverlay 14.

In the present embodiment, for example, a commercially available coverlay material is used that has a coverlay base material 14a that is a polyimide film with a thickness of 25 μm, same as the inner layer insulating base material 11, and a coverlay adhesive layer 14b formed on one side of the coverlay base material 14a. As described above, the exposed portion 12tt is not covered by the coverlay 14, so that the conductor layer is left exposed.

The coverlay 14 is applied to the entire surface except for the terminal area (exposed portion 12tt) of the lead pattern portion At, including the inner layer circuit pattern portion Acf. However, a method is also possible in which, with the object of reducing the total thickness of the layered circuit pattern portion Acs, improving the interlayer adhesive properties of the layered circuit pattern portion Acs, and the like, the coverlay 14 is not provided on the layered circuit pattern portion Acs. Also, with the object of increasing reliability of through hole formation between layers, a configuration is also possible in which the coverlay 14 is excluded from the area around a through hole.

Next, surface treatment is performed on the exposed portion 12tt, such as gold plating, tin plating, rust-proofing treatment, or the like. For example, when performing metal plating, after performing polishing or soft etching of the surface of the conductor layer, applying a plating resist to a portion where plating is not necessary, and performing pretreatment such as seeding, nickel plating and gold plating are performed in order.

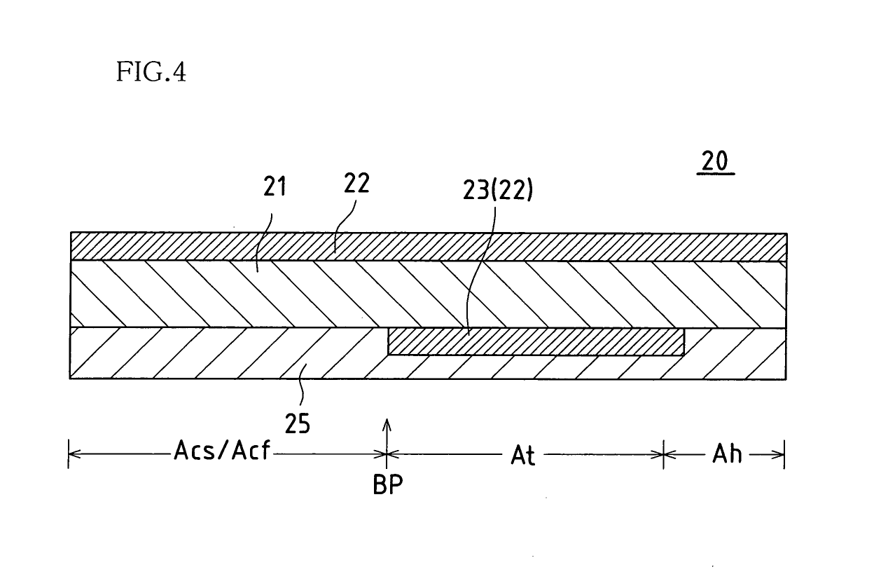

FIG. 4 is a cross-sectional view of an outer layer base material prepared for layering on the inner layer base material shown in FIG. 3.

Next, an outer layer base material 20, and an interlayer adhesive layer 25 that fastens the outer layer base material 20 to the inner layer base material 10, are prepared. The outer layer base material 20 is configured with an outer layer insulating base material 21 that serves as an outer layer core, and a conductor layer 22 formed on the surface of the outer layer insulating base material 21. The interlayer adhesive layer 25 is formed by layering on the face where the outer layer base material 20 faces the inner layer base material 10.

For example, a commercially available double-sided printed wiring board material (double-sided wiring base material), in which copper foil (the conductor layer 22) is layered on a glass epoxy resin core material (the outer layer insulating base material 21) with a thickness of 0.1 mm, was used as the outer layer base material 20.

The material quality and thickness of the outer layer base material 20, same as the inner layer base material 10, is not directly related to the configuration of the present invention, and so according to the necessary properties of the multilayer printed wiring board to be manufactured, it is possible to use basically any material that can be used for a multilayer printed wiring board material; for example, paper, polyester reinforced with aramid resin fiber or another fiber, polyether ketone, phenol, fluorocarbon resin, another resin, or the like can be used.

An epoxy resin in a semi-hardened state and in a sheet-like form, which is commercially available as a multilayer printed wiring board material, was used as the interlayer adhesive layer 25. The material quality and thickness of the interlayer adhesive layer 25, same as the outer layer base material 20, may be freely selected as necessary.

First, by forming an appropriate etching resist on the surface of the conductor layer 22 (copper foil) disposed on both sides of the outer layer base material 20, and etching (patterning) the conductor layer 22 with an appropriate etchant, a metal layer dummy pattern 23 is formed (dummy pattern formation step). The conductor layer 22 on the face opposite to the face where the dummy pattern 23 is formed is left as-is on the entire face without etching.

By configuring the outer layer base material 20 with double-sided wiring base material, it is possible to form the dummy pattern 23 using a conductor layer (metal layer) on one side, so it is possible to form the dummy pattern 23 very easily and with good productivity.

The dummy pattern 23 is formed so as to indicate the range that becomes the lead pattern portion At (border of the lead pattern portion At) in the completed multilayer printed wiring board. In FIG. 4, a state is shown in which the dummy pattern 23 is formed in a shape corresponding to the entire range of the lead pattern portion At, but the shape of the dummy pattern 23 may also be line-like marks, band-like marks or the like that indicate corner portions and each side of the lead pattern portion At.

Also, dummy pattern 23 is configured to have at least part of a shape (pattern) that indicates the border position BP of the layered circuit pattern portion Acs and the lead pattern portion At. That is, the dummy pattern 23 is configured to have a pattern that corresponds to the border of the layered circuit pattern portion Acs and the lead pattern portion At. With this configuration, the dummy pattern 23 can be formed with the border of the layered circuit pattern portion Acs and the lead pattern portion At easily and precisely delineated. Also, in order to clearly indicate the border, it is desirable that a pattern that indicates the border position BP is at least formed in a band-like manner at the border.

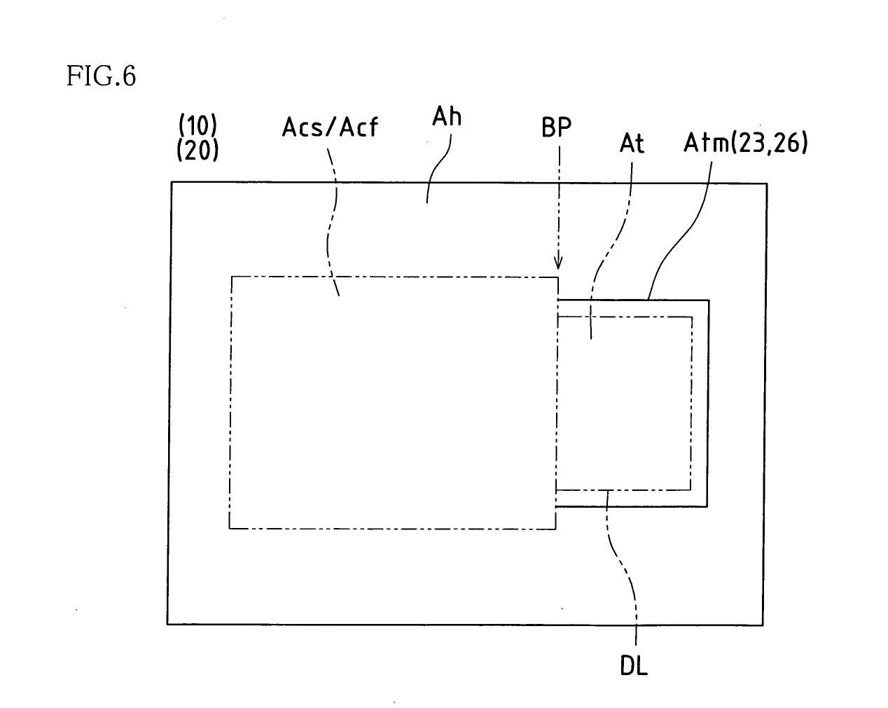

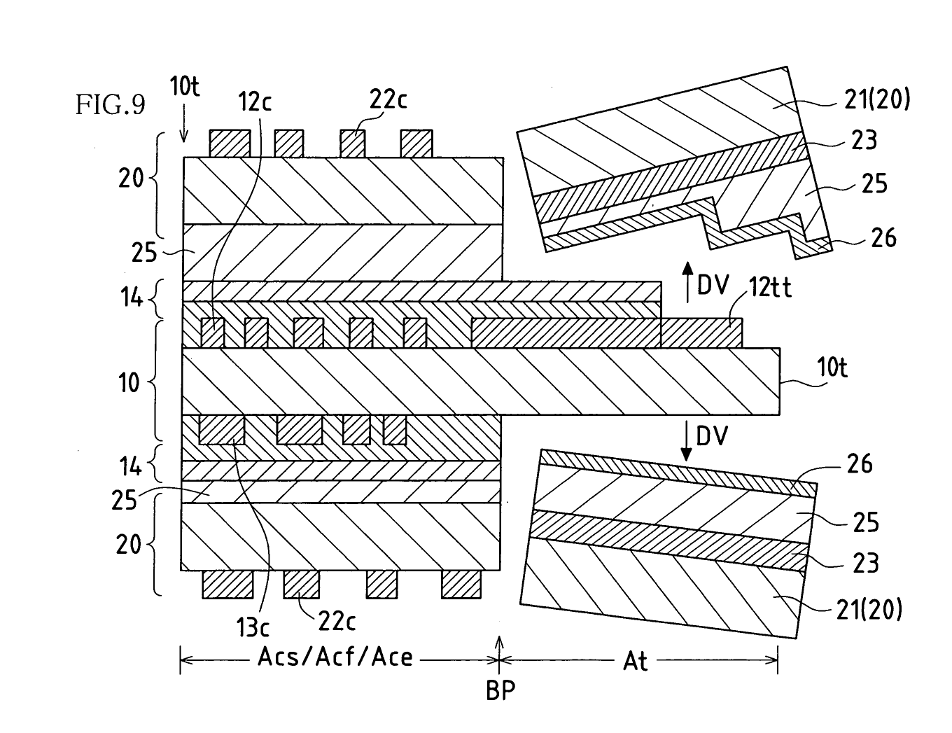

As described above, the dummy pattern 23 may be formed with any shape viewed from above, as long as the shape indicates the range of the lead pattern portion At. That is, the dummy pattern 23 may be formed with any shape viewed from above, as long as the shape can act as a guide when specifying the application position of a lead portion corresponding resin film 26 (see FIG. 6) described below, and can act as a guide that specifies a cutting position (cutting position DL; see FIG. 8) when forming an outer circumferential edge 10t (see FIG. 9) of the multilayer printed wiring board.

The interlayer adhesive layer 25 is formed by layering the interlayer adhesive layer 25 on the surface of the outer layer base material 20 where the dummy pattern 23 is formed (interlayer adhesive layer formation step). In the present embodiment, a four-layer structure is adopted in which the outer layer base material 20 is disposed on both sides of the inner layer base material 10, so another outer layer base material 20 that is disposed on the other side of the inner layer base material 10 is likewise prepared.

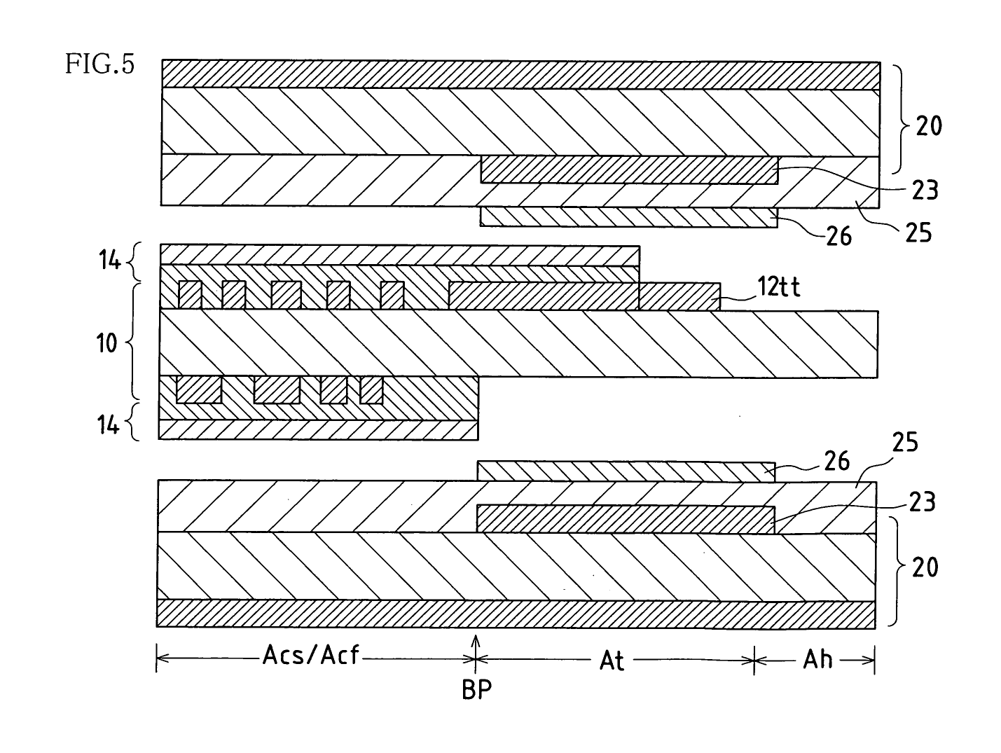

FIG. 5 is a cross-sectional view that shows an arrangement when a lead portion corresponding resin film is applied to the outer layer base material shown in FIG. 4 and layered on the inner layer base material. FIG. 6 is a plan view that conceptually shows a layering relationship of the inner layer base material and the outer layer base material shown in FIG. 5, viewed from above.

After the interlayer adhesive layer formation step, the lead portion corresponding resin film 26 formed corresponding to the range of the lead pattern portion At is applied, corresponding to the dummy pattern 23, to the surface of the interlayer adhesive layer 25 (FIG. 5; resin film application step). Because the surface of the interlayer adhesive layer 25 is covered with the lead portion corresponding resin film 26, it is possible to adopt a configuration such that the lead pattern portion At of the inner layer base material 10 is not fastened to the outer layer base material 20 when the inner layer base material 10 and the outer layer base material 20 are layered.

The lead portion corresponding resin film 26 is formed in advance by preprocessing with a die or the like with a shape corresponding to the range of the lead pattern portion At (i.e., a range where fastening to the outer layer base material 20 is not desired), and applied to the interlayer adhesive layer 25 with the position of the lead portion corresponding resin film 26 matched to that of the dummy pattern 23.

Accordingly, the lead portion corresponding resin film 26 is sought to be as thin as possible, and the lead portion corresponding resin film 26 is sought to be able to withstand temperature and heat when layering the inner layer base material 10 and the outer layer base material 20 (base material layering step). Also, performance is sought for the lead portion corresponding resin film 26 such that gas or contaminants are not produced when fastening layers, and there is not a reaction with the coverlay 14 or the exposed portion 12tt of the lead pattern portion At, and there is no fastening to the inner layer base material 10 and the coverlay 14, and the like.

In the present embodiment, it is desirable that the lead portion corresponding resin film 26, same as the coverlay 14, is constituted of polyimide resin, and is provided with a surface that can be bonded to the interlayer adhesive layer 25 (tacky, sticky, adhesive, or the like). For example, it is possible to employ a commercially available coverlay material in which an adhesive layer has been formed on one side of polyimide resin.

That is, by using the dummy pattern 23 as a positioning guide, tackiness provided by an adhesive layer formed on one face of the lead portion corresponding resin film 26 is used to apply the lead portion corresponding resin film 26 to the surface of the interlayer adhesive layer 25 (temporarily fastened/affixed). With this configuration, it is possible to easily and precisely apply the lead portion corresponding resin film 26 to the interlayer adhesive layer 25.

Also, a configuration can be adopted in which the lead portion corresponding resin film 26 is constituted of polyimide resin, and for example, a heat sensitive adhesive is applied to the surface that faces the interlayer adhesive layer 25. By employing a heat sensitive adhesive that can be applied and formed, adhesiveness of the lead portion corresponding resin film 26 can easily be insured, and it is possible to make pressure applied during layering (during heating) still more uniform, so it is possible to form the lead pattern portion At with greater precision.

When the interlayer adhesive layer 25 formed on the surface of the outer layer base material 20 has tackiness or stickiness such that it is possible to temporarily fasten the lead portion corresponding resin film 26, an adhesive layer formed on one face of the lead portion corresponding resin film 26 is unnecessary, and for example, it is possible to use simply a polyimide film or the like.

Also, in consideration of a difference in displacement or the like in outer shape processing of a subsequent step (outer circumferential edge formation step; see FIG. 8), other than the border position BP of the lead pattern portion At and the layered circuit pattern portion Acs, the outer shape position of the lead pattern portion At is an excess outer shape Atm (FIG. 6) that is slightly larger than the actual outer shape (see FIGS. 8 and 9; the outer circumferential edge 10t of the lead pattern portion At; position of the cutting line DL).

The dummy pattern 23 and the lead portion corresponding resin film 26 are formed in the same manner as the excess outer shape Atm. That is, the lead portion corresponding resin film 26 is formed extended to the outside of the outer circumferential edge 10t of the lead pattern portion At (position of cutting line DL).

With this configuration, because it is possible to reliably expose the lead portion corresponding resin film 26 at the outer circumferential edge 10t formed in an outer circumferential edge formation step described below, it is possible to very easily and precisely separate the lead portion corresponding resin film 26, the interlayer adhesive layer 25, and the outer layer base material 20 from the inner layer base material 10. Note that below, simply the lead pattern portion At is described, without distinguishing the excess outer shape Atm.

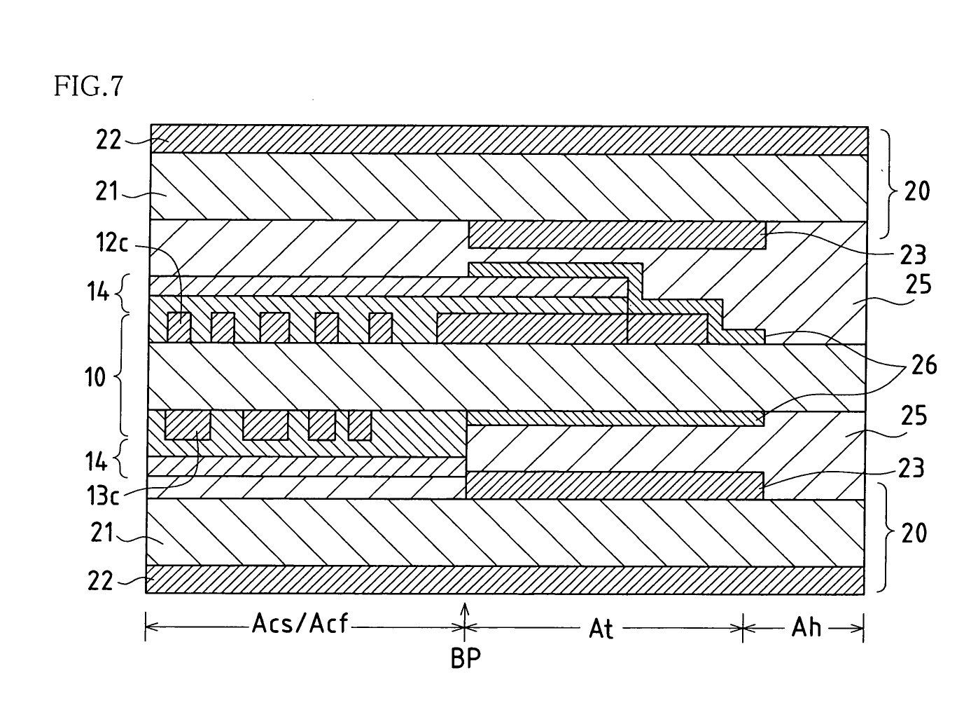

FIG. 7 is a cross-sectional view that shows a state in which the inner layer base material and the outer layer base material shown in FIGS. 5 and 6 have been layered.

After the lead portion corresponding resin film 26 is applied (temporarily fastened) to the interlayer adhesive layer 25, the position of the lead portion corresponding resin film 26 is matched to that of the lead pattern portion At, and the outer layer base material 20 is layered/fastened to the inner layer base material 10 via the interlayer adhesive layer 25 (base material layering step). In the base material layering step, a layering press apparatus or the like is employed.

In the present embodiment, layering and fastening are performed with the outer layer base material 20 disposed facing the inner layer base material 10 on both sides of the inner layer base material 10, so that the layered circuit pattern portion Acs has a four-layer structure.

In the present embodiment, the layered state of the lead pattern portion At is a state in which a space is not produced, as in the layered state of the layered circuit pattern portion Acs. That is, because a space is not produced between the lead pattern portion At and the layered circuit pattern portion Acs, unlike with the conventional technology, a difference in height between the lead pattern portion At and the layered circuit pattern portion Acs is greatly suppressed.

That is, because incontinuity of thickness between the lead pattern portion At and the layered circuit pattern portion Acs is eliminated, in the lead pattern portion At and the layered circuit pattern portion Acs, regardless of their respective regions, the outer layer base material 20 is uniformly pressed against the inner layer base material 10, and so there is no risk of distortion due to uneven pressure on the lead pattern portion At.

That is, the difference in thickness (height difference) of the layered materials between the layered circuit pattern portion Acs and the lead pattern portion At does not exceed the thickness of one sheet of the lead portion corresponding resin film 26, and can be at most several tens of μm. Also, the interlayer adhesive layer 25, which has fluidity, is filled between the inner layer base material 10 and the outer layer base material 20, so even the difference in height described above can be absorbed by the flow of the interlayer adhesive layer 25 during layering.

Accordingly, there is no risk of damage to the lead pattern portion At due to a difference in height between the lead pattern portion At and the layered circuit pattern portion Acs, and so it is possible to greatly improve the anti-flexibility properties of the lead pattern portion At the border position BP.

Further, because the lead portion corresponding resin film 26 is closely fitted to the lead pattern portion At during layering, a gap does not occur due to a difference in the number of layers as with the conventional technology, and so an adhesive phenomenon due to the interlayer adhesive layer 25 flowing and protruding out to the lead pattern portion At, which causes defective goods, does not occur. That is, because the interlayer adhesive layer 25 does not protrude to an unintended portion to cause defects, it is possible to improve product quality/step yield.

FIG. 8 is a cross-sectional view that shows a state in which a layered circuit pattern has been configured by forming an outer layer circuit pattern on the outer layer base material layered on the inner layer base material in FIG. 7.

After layering is finished, through hole processing/via hole processing and outer layer patterning are performed with a procedure like that used in a conventional method. By performing outer layer patterning, the conductor layer 22 of the outer layer base material 20 layered on the inner layer base material 10 is patterned to form outer layer circuit patterns 22c that correspond respectively to the inner layer circuit pattern 12c and the inner layer circuit pattern 13c. The outer layer circuit patterns 22c constitute the outer layer circuit pattern portion Ace. That is, the conductor layer 22 of the outer layer base material 20 is patterned to form the outer layer circuit pattern portion Ace corresponding to the inner layer circuit pattern portion Acf (outer layer pattern formation step).

After the outer layer pattern formation step, necessary processing treatment is performed, such as surface treatment like plating, rust-proofing treatment, and the like, solder resist treatment, silk printing treatment, and the like.

After necessary processing treatment, outer shape processing (outer circumferential edge formation step) is performed in which the layered circuit pattern portion Acs constituted by the inner layer circuit pattern portion Acf and the outer layer circuit pattern portion Ace, and the lead pattern portion At, are cut from the discarded plate portion Ah (the surrounding inner layer base material 10 and outer layer base material 20) at the cutting line DL, thus forming the outer circumferential edge 10t (see FIG. 9) of the layered circuit pattern portion Acs and the lead pattern portion At. That is, the outer circumferential edge formation step is provided before an outer layer base material removal step described below.

FIG. 9 is a cross-sectional view that shows a state in which a multilayer printed wiring board is completed by forming outer circumferential edges of the layered circuit pattern portion and the lead pattern portion in FIG. 8, and then removing the outer layer base material that corresponds to the lead pattern portion from the inner layer base material.

After cutting from the surrounding inner layer base material 10 and outer layer base material 20 at the cutting line DL to form the outer circumferential edge 10t of the layered circuit pattern portion Acs and the lead pattern portion At, the lead portion corresponding resin film 26 is separated (peeled away) from the inner layer base material 10, and thus the interlayer adhesive layer 25 and the outer layer base material 20 layered on the lead portion corresponding resin film 26 are removed (outer layer base material removal step).

In the lead pattern portion At, there is no fastening to the outer layer base material 20 because the lead portion corresponding resin film 26 disposed corresponding to the lead pattern portion At has been layered. Accordingly, when the outer layer base material 20 is peeled away from the outer circumferential edge 10t in the direction indicated by arrow DV, it is possible to separate the lead portion corresponding resin film 26, the interlayer adhesive layer 25, and the outer layer insulating base material 21 (outer layer base material 20) from the lead pattern portion At.

Also, there is incontinuity of adhesive strength between the inner layer base material 10 and the outer layer base material 20 at the border position BP of the layered circuit pattern portion Acs and the lead pattern portion At. That is, there is adequate strength on the layered circuit pattern portion Acs side because the inner layer base material 10 and the outer layer base material 20 are fastened by the interlayer adhesive layer 25, but on the lead pattern portion At side, there is almost no adhesive strength between the inner layer base material 10 and the outer layer base material 20 due to the presence of the lead portion corresponding resin film 26.

Accordingly, the outer layer base material 20 is easily folded at the border position BP and removed from the lead pattern portion At (inner layer base material 10), and thus the multilayer printed wiring board according to the present embodiment is completed (outer layer base material removal step).

The outer layer base material 20, in consideration of the ease of folding at the border position BP, is desirably constituted by material having hardness (for example, such as glass epoxy resin core material in the present embodiment).

After exposing the lead portion corresponding resin film 26 at the outer circumferential edge 10t in the outer circumferential edge formation step by cutting at the cutting line DL, the lead portion corresponding resin film 26 and the outer layer base material 20 corresponding to the lead portion corresponding resin film 26 are removed in the outer layer base material removal step, so it is possible to very easily remove the outer layer base material 20 from the inner layer base material 10 (lead pattern portion At).

As the outer shape processing, other than the method shown in FIGS. 8 and 9 (forming the outer circumferential edge 10t in the outer circumferential edge formation step, and then removing the outer layer base material 20 in the outer layer base material removal step), it is also possible to perform middle hole processing that temporarily cuts only the outer layer base material 20 corresponding to an outline portion of the lead pattern portion At when viewed from above with a die, router (channel cutting device), or the like, and performing outer shape processing (outer circumferential edge formation step) that forms the outer circumferential edge 10t after removing the outer layer base material 20 corresponding to the lead pattern portion At (outer layer base material removal step). With this configuration, it is possible to form the outer circumferential edge 10t corresponding to the lead pattern portion At cleanly and precisely.

As described above, the method for manufacturing a multilayer printed wiring board according to the present embodiment is a method for manufacturing a multilayer printed wiring board provided with the flexible inner layer base material 10 having the inner layer circuit pattern portion Acf and the lead pattern portion At extended from the inner layer circuit pattern portion Acf, and the outer layer base material 20 having the outer layer circuit pattern portion Ace layered on the inner layer circuit pattern portion Acf, the method being provided with an inner layer pattern formation step of pattering the conductor layer 12 (13) of the inner layer base material 10 to form the inner layer circuit pattern portion Acf and the lead pattern portion At, a dummy pattern formation step of forming the metal layer dummy pattern 23 on the outer layer base material 20, the dummy pattern indicating the range of the lead pattern portion At, an interlayer adhesive layer formation step of forming the interlayer adhesive layer 25 on the surface of the outer layer base material 20 where the dummy pattern 23 has been formed, a resin film application step of applying, corresponding to the dummy pattern 23, the lead portion corresponding resin film 26 to the interlayer adhesive layer 25, the lead portion corresponding resin film 26 being formed corresponding to the range of the lead pattern portion At, a base material layering step of layering the outer layer base material 20 on the inner layer base material 10 via the interlayer adhesive layer 25, with the position of the lead portion corresponding resin film 26 matched to the position of the lead pattern portion At, an outer layer pattern formation step of forming the outer layer circuit pattern portion Ace corresponding to the inner layer circuit pattern portion Acf by patterning the conductor layer 22 of the outer layer base material 20 layered on the inner layer base material 10, and an outer layer base material removal step of separating the lead portion corresponding resin film 26 from the inner layer base material 10 to remove the interlayer adhesive layer 25 and the outer layer base material 20 layered on the lead portion corresponding resin film 26.

With this configuration, a height difference due to the thickness of the lead portion corresponding resin film 26 is absorbed, so that it is possible to layer the outer layer base material 20 and the inner layer base material 10 by applying pressure uniformly, in a state in which the lead pattern portion At and the outer layer base material 20 are not fastened. That is, even when the interlayer adhesive layer 25 and the outer layer base material 20 are not processed in advance, it is possible to layer the inner layer base material 10 and the outer layer base material 20 without fastening the interlayer adhesive layer 25 to the lead pattern portion At, so it is possible to easily and precisely separate the lead portion corresponding resin film 26, the interlayer adhesive layer 25, and the outer layer base material 20 from the inner layer base material 10.

Accordingly, it is possible to form a precisely positioned lead pattern portion At with distortion by the outer layer base material 20 or affecting of the interlayer adhesive layer 25 to the lead pattern portion At in the base material layering step or the outer layer base material removal step eliminated, and so by eliminating processing defects such as damage to the lead pattern portion At or protrusion of adhesive from the interlayer adhesive layer 25 eliminated, the cutting face at the border between the layered circuit pattern portion Acs and the lead pattern portion At can be clean and distortion free, so it is possible to manufacture, with good productivity, a multilayer printed wiring board having a lead pattern portion At with high precision and high bendability.

As described above, in the present embodiment, it is not necessary to perform slit processing/hole processing in advance on the outer layer base material 20 and the interlayer adhesive layer 25, so processing steps can be simplified, and height differences due to processing do not occur, so an effect is obtained that it is possible to prevent processing defects such as damage to the lead pattern portion At or protrusion of the adhesive from the interlayer adhesive layer 25. That is, effects are obtained that problems such as soiling or affixing of foreign matter by the adhesive (interlayer adhesive layer 25) do not occur, and a maintenance step is not necessary for the adhesive (interlayer adhesive layer 25) processing die, and positioning of the interlayer adhesive layer 25 and the outer layer base material 20 relative to the inner layer base material 10 becomes easy.

### Embodiment 2

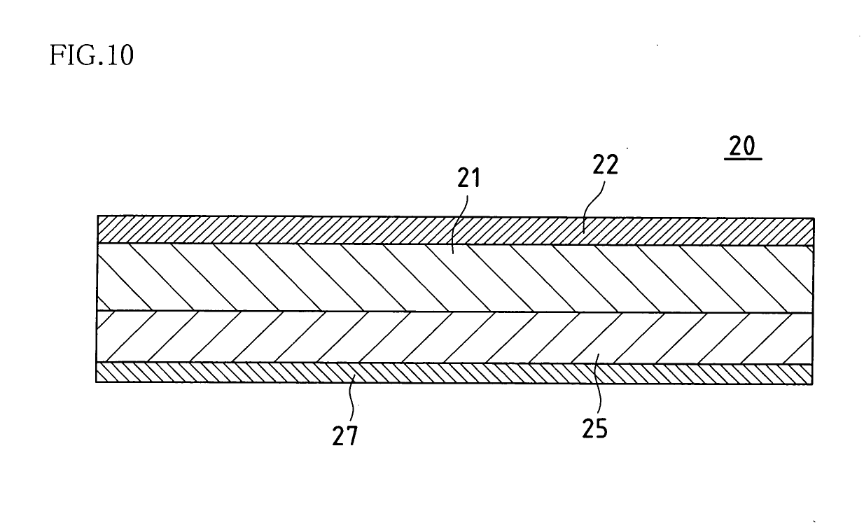

A method for manufacturing a multilayer printed wiring board according to Embodiment 2 will be described with reference to FIGS. 10 to 13.

The method for manufacturing a multilayer printed wiring board according to the present embodiment is basically the same as in Embodiment 1, but the method for processing the outer layer base material 10 and the method of forming the lead portion corresponding resin film 26 are different. Below, mainly differing points will be described while appropriately citing the reference numerals of Embodiment 1.

The point of patterning the conductor layers 12 (13) of the inner layer base material 10 to form the inner layer circuit pattern portion Acf and the lead pattern portion At (inner layer pattern formation step) is the same as in Embodiment 1, and so a description thereof is omitted here.

FIG. 10 is a cross-sectional view of a multilayer printed wiring board obtained by layering an interlayer adhesive layer and a temporary fastening resin film to the outer layer base material prepared for layering on the inner layer base material applied in a method for manufacturing a multilayer printed wiring board according to Embodiment 2 of the present invention.

The interlayer adhesive layer 25 is formed by layering the interlayer adhesive layer 25 on the face opposite to the inner layer base material 10 of the outer layer base material 20 (interlayer adhesive layer formation step). In the present embodiment, a fiberglass reinforced epoxy one-sided printed wiring board material in which copper foil has been applied to one side is used as the outer layer base material 20. The material quality, thickness, and the like of the outer layer base material 20 and the interlayer adhesive layer 25, same as in Embodiment 1, may be selected according to the necessary properties.

In Embodiment 1, the lead portion corresponding resin film 26 formed in advance corresponding to the range of the lead pattern portion At, which is a portion where adhesion is not desired, was applied one by one at a corresponding position (the position of the dummy pattern 23). However, in this method, because it is necessary to position and apply lead portion corresponding resin films 26 one by one, and necessary to form them in advance corresponding to a necessary shape, when it is necessary in the processing work for one sheet to apply a plurality of sheets of lead portion corresponding resin film 26, this takes much labor, and accordingly there is the problem that the likelihood is high that processing defects will occur such as positional displacement of application, forgotten application, or the like.

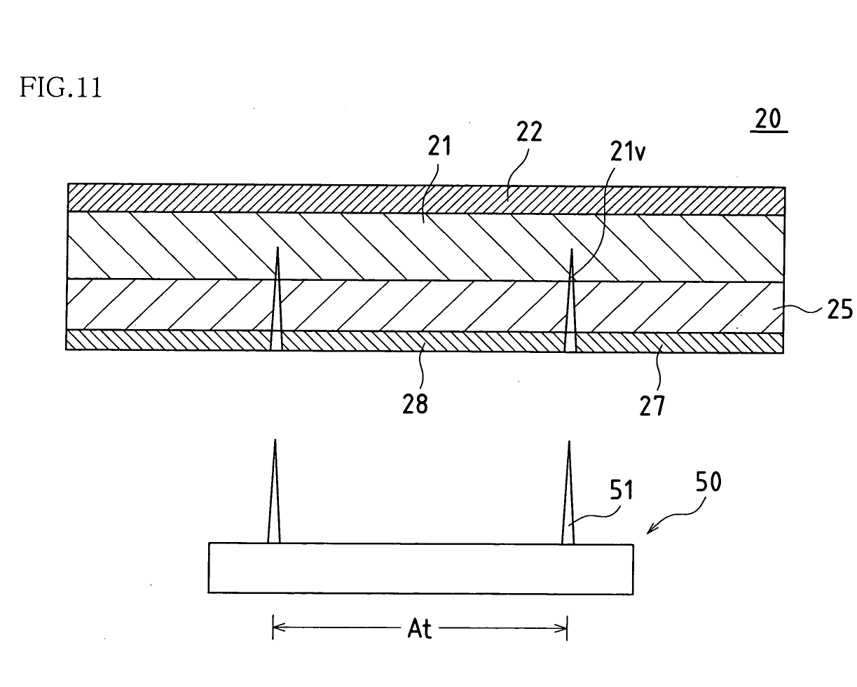

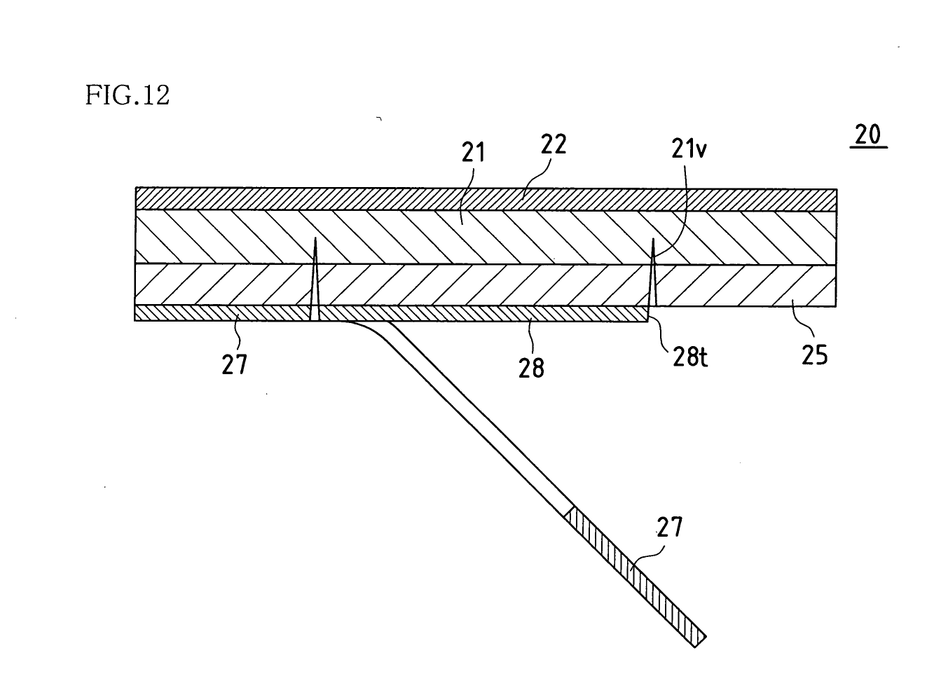

Therefore, in the present embodiment, a temporary fastening resin film 27 for forming a lead portion corresponding resin film 28 (see FIGS. 11 and 12) on the interlayer adhesive layer 25 is layered (temporarily fastened) on approximately the entire face (surface) of the interlayer adhesive layer 25 (resin film temporary fastening step). By forming the temporary fastening resin film 27 on approximately the entire face, it is possible to ignore positioning precision of the temporary fastening resin film 27. Also, for example, a commercially available coverlay material having the same properties as the lead portion corresponding resin film 26 in Embodiment 1 was used as the temporary fastening resin film 27.

Also, the temporary resin film 27 is not necessarily fastened to the entire face; the temporary resin film 27 may have any size such that it is possible to ignore positioning precision of the temporary fastening resin film 27 when fastened, provided that the size is such that the lead portion corresponding resin film 28 can be formed by performing cutting in a resin film cutting step and peeling away in a resin film peeling step, described below. Also, in this case, it is desirable that an ear portion for peeling is provided in an edge portion.

FIG. 11 is a cross-sectional view that shows a state in which the lead portion corresponding resin film has been delineated by cutting the temporary fastening resin film shown in FIG. 10.

The temporary fastening resin film 27 formed on the entire face of the interlayer adhesive layer 25 is, for example, cut with a pinnacle-type, Thomson-type, or other blade 50 (blade tip 51). That is, with the blade tip 51, the temporary fastening resin film 27 is cut along the range (outer circumference) of the lead pattern portion At (resin film cutting step), delineating the lead portion corresponding resin film 28 corresponding to the range of the lead pattern portion At.

A cut-in 21v provided by cutting of the temporary fastening resin film 27 pierces through the temporary fastening resin film 27 and the interlayer adhesive layer 25, and is formed approximately up to the outer layer base material 20 (outer layer insulating base material 21) (half-cut). With this configuration, in a state with the outer shape of the outer layer base material 20 maintained, the lead portion corresponding resin film 28 is cut and separated from the surrounding temporary fastening resin film 27.

FIG. 12 is a cross-sectional view that shows a state in which the lead portion corresponding resin film has been formed by peeling away the temporary fastening resin film shown in FIG. 11.

After the temporary fastening resin film 27 is cut to delineate the lead portion corresponding resin film 28, the temporary fastening resin film 27 that is other than the lead portion corresponding resin film 28 (the temporary fastening resin film 27 that becomes unnecessary in a base material layering step below) is peeled away, and the temporary fastening resin film 27 that corresponds to the range of the lead pattern portion At remains as the lead portion corresponding resin film 28 (resin film peeling step). That is, the lead portion corresponding resin film 28 is formed on the outer layer base material 20 (interlayer adhesive layer 25).

At a cut edge 28t of the lead portion corresponding resin film 28, during half-cutting, a greater pressure due to pressing of the blade tip 51 than at other temporarily fastened locations is applied, and cutting is performed so as to cut into the interlayer adhesive layer 25, so it is possible to easily remove the unnecessary temporary fastening resin film 27, while leaving the lead portion corresponding resin film 28 portion remaining.

With this configuration, because the work of positioning the lead portion corresponding resin film 26 one by one during application that was necessary in Embodiment 1 is not necessary, it is possible to reduce man-hours, and the dummy pattern 23 that was necessary as a positioning guide in application of the lead portion corresponding resin film 26 is not necessary. Accordingly, it is possible to greatly reduce processing man-hours and materials, and without concern for forgetting application, or positional displacement, and so it is possible to greatly reduce processing defects and improve positional precision.

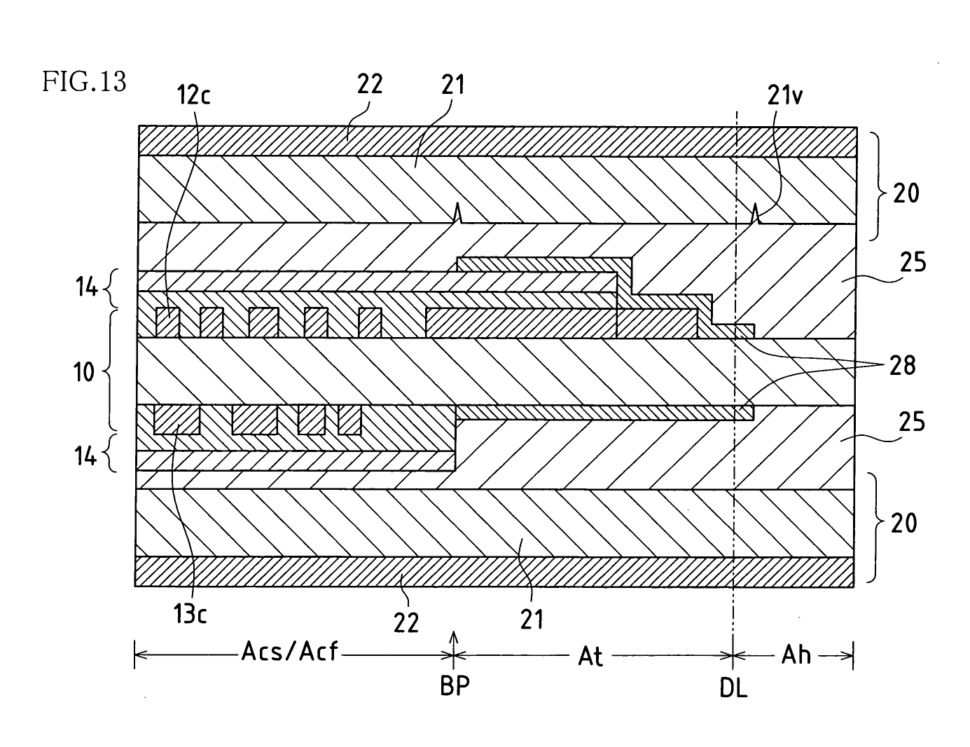

FIG. 13 is a cross-sectional view that shows a general state in which the lead portion corresponding resin film shown in FIG. 12 has been applied and the inner layer base material and the outer layer base material have been layered.

After the lead portion corresponding resin film 28 is formed in the resin film peeling process, the position of the lead portion corresponding resin film 28 is matched to that of the lead pattern portion At, and the outer layer base material 20 is layered on the inner layer base material 10 via the interlayer adhesive layer 25 (base material layering step). Except for not having the dummy pattern 23, the configuration is the same as in FIG. 7 in Embodiment 1, and so a detailed description is omitted here.

Subsequently, same as in Embodiment 1, after the conductor layer 22 of the outer layer base material 20 layered on the inner layer base material 10 is patterned to form the outer layer circuit pattern portion Ace corresponding to the inner layer circuit pattern portion Acf (outer layer pattern formation step), and the outer circumferential edge is formed (outer circumferential edge formation step), the lead portion corresponding resin film 28 is separated from the inner layer base material 10, and thus the interlayer adhesive layer 25 and the outer layer base material 20 layered on the lead portion corresponding resin film 28 are removed (outer layer base material removal step).

Also, at the border position BP of the lead pattern portion At and the layered circuit pattern portion Acs, the outer layer base material 20 (outer layer insulating base material 21) was half-cut when the lead portion corresponding resin film 28 was formed, and the cut-in 21v operates as a so-called V-notch. Accordingly, in the outer layer base material removal step, when the lead portion corresponding resin film 28 (and the outer layer base material 20) is peeled, the outer layer base material 20 is automatically folded at the cut-in 21v, so that it is possible to easily and cleanly remove the outer layer base material 20. A clean cut face can be formed corresponding to the cut-in 21v at the border position BP.

Also, the outer circumferential edge formation step in the present embodiment can be the same as in Embodiment 1.

As described above, the method for manufacturing a multilayer printed wiring board according to the present embodiment is a method for manufacturing a multilayer printed wiring board provided with the flexible inner layer base material 10 having the inner layer circuit pattern portion Acf and the lead pattern portion At extended from the inner layer circuit pattern portion Acf, and the outer layer base material 20 having the outer layer circuit pattern portion Ace layered on the inner layer circuit pattern portion Acf, the method being provided with an inner layer pattern formation step of pattering the conductor layer 12 (13) of the inner layer base material 10 to form the inner layer circuit pattern portion Acf and the lead pattern portion At, an interlayer adhesive layer formation step of forming the interlayer adhesive layer 25 on the outer layer base material 20, a resin film temporary fastening step of temporarily fastening the temporary fastening resin film 27 for forming the lead portion corresponding resin film 28 on the surface of the interlayer adhesive layer 25, a resin film cutting step of cutting the temporary fastening resin film 27 along the range of the lead pattern portion At, a resin film peeling step of peeling away the temporary fastening resin film 27 to leave the temporary fastening resin film 27 that corresponds to the range of the lead pattern portion At as the lead portion corresponding resin film 28, a base material layering step of layering the outer layer base material 20 on the inner layer base material 10 via the interlayer adhesive layer 25, with the position of the lead portion corresponding resin film 28 matched to the position of the lead pattern portion At, an outer layer pattern formation step of forming the outer layer circuit pattern portion Ace corresponding to the inner layer circuit pattern portion Acf by patterning the conductor layer 22 of the outer layer base material 20 layered on the inner layer base material 10, and an outer layer base material removal step of separating the lead portion corresponding resin film 28 from the inner layer base material 10 to remove the interlayer adhesive layer 25 and the outer layer base material 20 layered on the lead portion corresponding resin film 28.

With this configuration, the same working effects as in Embodiment 1 are obtained. Further, because the cut-in 21v is formed in the outer layer base material 20, folding of the outer layer base material 20 corresponding to the lead pattern portion At is easy, and the cut shape at the border of the lead pattern portion At and the layered circuit pattern portion Acs is cleanly finished. Also, it is not necessary to use double-sided printed wiring board material (double-sided wiring base material) as the outer layer base material 20, and it is also unnecessary to have an etching step, so it is possible to simplify the outer layer base material 20.

Accordingly, the man-hours of the steps of forming the lead portion corresponding resin film 28 (the resin film temporary fastening step, the resin film cutting step, and the resin film peeling step) are reduced, and so it is possible to simplify the steps of forming the lead portion corresponding resin film 28, and increase precision. Also, there are the advantages that it is possible to eliminate processing defects such as forgetting application of the lead portion corresponding resin film 28, and high-precision positioning is possible.

### Embodiment 3

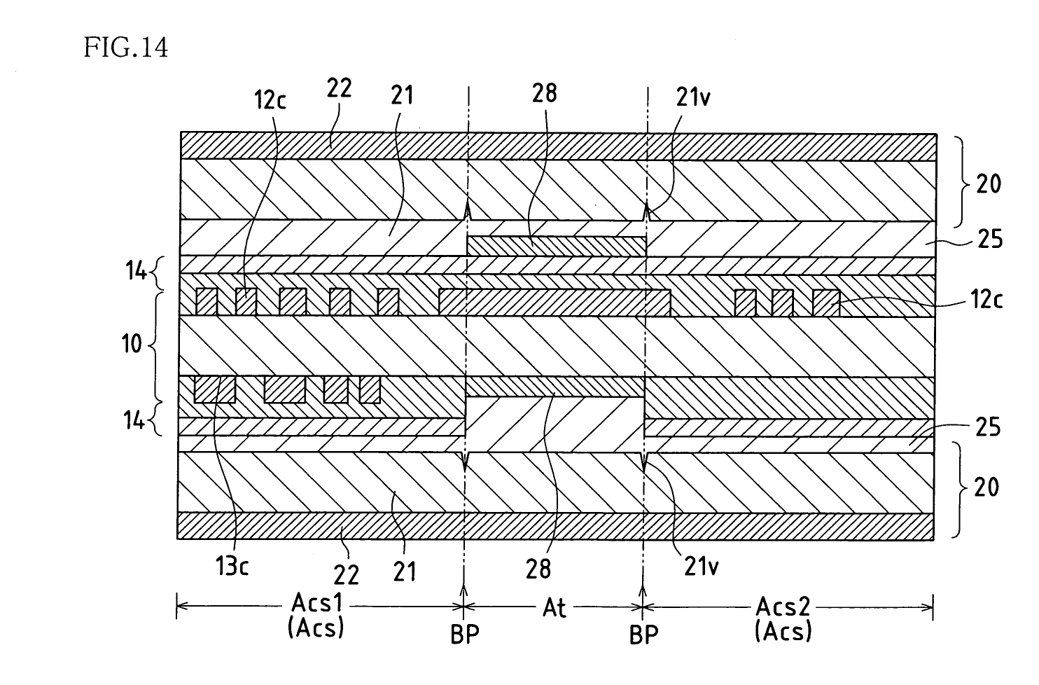

A method for manufacturing a multilayer printed wiring board according to Embodiment 3 will be described with reference to FIG. 14.

FIG. 14 is a cross-sectional view of a multilayer printed wiring board obtained by layering the inner layer base material and the outer layer base material, employing the lead portion corresponding resin film according to Embodiment 2, in a method for manufacturing a multilayer printed wiring board according to Embodiment 3 of the present invention.

The method for manufacturing a multilayer printed wiring board according to the present embodiment is basically the same as in Embodiment 2, but the present embodiment differs in that a multilayer printed wiring board (common name: folding-type printed wiring board) is employed in which a plurality of layered circuit pattern portions Acs (layered circuit pattern portion Acs 1 and layered circuit pattern portion Acs 2: referred to as layered circuit pattern portion Acs when not necessary to distinguish) are connected and joined in the lead pattern portion At. Below, mainly differing points will be described while appropriately citing the reference numerals of Embodiments 1 and 2.

The basic steps are the same as in Embodiment 2. The state shown in FIG. 14 is established by the base material layering step. Because the layered circuit pattern portion Acs 1 and the layered circuit pattern portion Acs 2 are connected to each other in the lead pattern portion At, so a border position BP is formed at two locations corresponding respectively to both edges of the lead pattern portion At. Cut-ins 21v are formed corresponding to the border positions BP.

After the base material layering step, same as in Embodiment 2, through the outer layer pattern formation step, at a portion other than the border position BP of the layered circuit pattern portion Acs and the lead pattern portion At, the layered circuit pattern portion Acs and the lead pattern portion At are cut from the surrounding inner layer base material 10 and the outer layer base material 20 to form the outer circumferential edge 10t of the layered circuit pattern portion Acs and the lead pattern portion At (in FIG. 14, disposed to on the side facing the front of the drawing and on the side facing the paper face (rear)) (outer circumferential edge formation step). After the outer circumferential edge formation step, in the outer layer base material 20, a portion that corresponds to the lead pattern portion At is folded up and removed using the cut-ins 21v (outer layer base material removal step). Accordingly, the outer layer base material 20 is easily folded at the border position BP and removed from the lead pattern portion At (inner layer base material 10), and thus the multilayer printed wiring board according to the present embodiment is completed (outer layer base material removal step).

Also, the outer circumferential edge formation step in the present embodiment can be the same as in Embodiment 1.

In the present embodiment as well, the same working effects as in Embodiments 1 and 2 are obtained. Also, the uses (scope of applicability) of the multilayer printed wiring board can be expanded.

### Embodiment 4

With the present embodiment, it is possible to simplify the steps of the method for manufacturing a multilayer printed wiring board according to Embodiment 1 by omitting the dummy pattern 23 (not shown). That is, in Embodiment 1, the lead portion corresponding resin film 26 is applied corresponding to the dummy pattern 23, but as in Embodiment 2, it is possible to appropriately position and apply the lead portion corresponding resin film 26 without using the dummy pattern 23. Because the basic steps are the same as in Embodiments 1 and 2, the reference numerals thereof will be appropriately cited in the description of the present embodiment.

In the present embodiment, the dummy pattern formation step of Embodiment 1 is omitted, the interlayer adhesive layer formation step in Embodiment 1 is changed to an interlayer adhesive layer formation step of forming the interlayer adhesive layer 25 on the outer layer base material 20, the resin film application step in Embodiment 1 is modified to a resin film formation step of forming the lead portion corresponding resin film 26 that corresponds to the lead pattern portion At on the surface of the interlayer adhesive layer 25, and the base material layering step in Embodiment 1 is modified to a base material layering step of positioning the lead portion corresponding resin film 26 on the lead pattern portion At and layering the outer layer base material 20 on the inner layer base material 10 via the interlayer adhesive layer 25.

Also, as a reference for the positioning in the resin film formation step, it is possible to form, in advance, a pattern that corresponds to the border position BP (edge portion of the lead pattern portion At) in the outer layer base material 20. Also, it is possible to delineate according to distance from the outer circumferential edge portion of the processing work.

Accordingly, the method for manufacturing a multilayer printed wiring board according to the present embodiment is a method for manufacturing a multilayer printed wiring board provided with the flexible inner layer base material 10 having the inner layer circuit pattern portion Acf and the lead pattern portion At extended from the inner layer circuit pattern portion Acf, and the outer layer base material 20 having the outer layer circuit pattern portion Ace layered on the inner layer circuit pattern portion Acf, the method being provided with an inner layer pattern formation step of pattering the conductor layer 12 (13) of the inner layer base material 10 to form the inner layer circuit pattern portion Acf and the lead pattern portion At, an interlayer adhesive layer formation step of forming the interlayer adhesive layer 25 on the outer layer base material 20, a resin film formation step of forming the lead portion corresponding resin film 26 corresponding to the lead pattern portion At on the surface of the interlayer adhesive layer 25, a base material layering step of layering the outer layer base material 20 on the inner layer base material 10 via the interlayer adhesive layer 25, with the position of the lead portion corresponding resin film 26 matched to the position of the lead pattern portion At, an outer layer pattern formation step of forming the outer layer circuit pattern portion Ace corresponding to the inner layer circuit pattern portion Acf by patterning the conductor layer 22 of the outer layer base material 20 layered on the inner layer base material 10, and an outer layer base material removal step of separating the lead portion corresponding resin film 26 from the inner layer base material 10 to remove the interlayer adhesive layer 25 and the outer layer base material 20 layered on the lead portion corresponding resin film 26.

With this configuration, the same working effects as in the method for manufacturing a multilayer printed wiring board according to Embodiment 1 are obtained, and it is possible to simplify the steps for forming the lead portion corresponding resin film 26, and also possible to further improve productivity.

The present invention may be embodied in various other forms without departing from the spirit or essential characteristics thereof. The embodiments disclosed in this application are to be considered in all respects as illustrative and not limiting. The scope of the invention is indicated by the appended claims rather than by the foregoing description, and all modifications or changes that come within the meaning and range of equivalency of the claims are intended to be embraced therein.

1. A method for manufacturing a multilayer printed wiring board, the multilayer printed wiring board being provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method comprising:
an inner layer pattern formation step of pattering a conductor layer of the inner layer base material to form the inner layer circuit pattern portion and the lead pattern portion,
a dummy pattern formation step of forming a metal layer dummy pattern on the outer layer base material, the dummy pattern indicating the range of the lead pattern portion,
an interlayer adhesive layer formation step of forming an interlayer adhesive layer on a surface of the outer layer base material where the dummy pattern has been formed,
a resin film application step of applying, corresponding to the dummy pattern, a lead portion corresponding resin film to the interlayer adhesive layer, the lead portion corresponding resin film being formed corresponding to the range of the lead pattern portion,
a base material layering step of layering the outer layer base material on the inner layer base material via the interlayer adhesive layer, with the position of the lead portion corresponding resin film matched to the position of the lead pattern portion,
an outer layer pattern formation step of pattering a conductor layer of the outer layer base material layered on the inner layer base material to form the outer layer circuit pattern portion corresponding to the inner layer circuit pattern portion, and
an outer layer base material removal step of separating the lead portion corresponding resin film from the inner layer base material to remove the interlayer adhesive layer and the outer layer base material layered on the lead portion corresponding resin film.

2. The method for manufacturing a multilayer printed wiring board according to claim 1, wherein the outer layer base material comprises a double-sided wiring base material, and a conductor layer on one side is etched to form the dummy pattern.

3. The method for manufacturing a multilayer printed wiring board according to claim 1, wherein the dummy pattern has a pattern that corresponds to a border of the layered circuit pattern portion and the lead pattern portion.

4. The method for manufacturing a multilayer printed wiring board according to claim 2, wherein the dummy pattern has a pattern that corresponds to a border of the layered circuit pattern portion and the lead pattern portion.

5. The method for manufacturing a multilayer printed wiring board according to claim 1, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

6. The method for manufacturing a multilayer printed wiring board according to claim 1, wherein the lead portion corresponding resin film is constituted from polyimide resin, and comprises a surface that can be bonded to the interlayer adhesive layer.

7. The method for manufacturing a multilayer printed wiring board according to claim 6, wherein the lead portion corresponding resin film is a polyimide film in which a heat sensitive adhesive has been applied to a surface that faces the interlayer adhesive layer.

8. The method for manufacturing a multilayer printed wiring board according to claim 1, wherein the lead portion corresponding resin film is formed extended to the outside of the outer circumferential edge of the lead pattern portion.

9. A method for manufacturing a multilayer printed wiring board, the multilayer printed wiring board being provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method comprising:
an inner layer pattern formation step of pattering a conductor layer of the inner layer base material to form the inner layer circuit pattern portion and the lead pattern portion,
an interlayer adhesive layer formation step of forming an interlayer adhesive layer on the outer layer base material,
a resin film temporary fastening step of temporarily fastening a temporary fastening resin film for forming a lead portion corresponding resin film on the surface of the interlayer adhesive layer,
a resin film cutting step of cutting the temporary fastening resin film along the range of the lead pattern portion,
a resin film peeling step of peeling away the temporary fastening resin film to leave the temporary fastening resin film that corresponds to the range of the lead pattern portion as the lead portion corresponding resin film,
a base material layering step of layering the outer layer base material on the inner layer base material via the interlayer adhesive layer, with the position of the lead portion corresponding resin film matched to the position of the lead pattern portion,
an outer layer pattern formation step of pattering a conductor layer of the outer layer base material layered on the inner layer base material to form the outer layer circuit pattern portion corresponding to the inner layer circuit pattern portion, and
an outer layer base material removal step of separating the lead portion corresponding resin film from the inner layer base material to remove the interlayer adhesive layer and the outer layer base material layered on the lead portion corresponding resin film.

10. The method for manufacturing a multilayer printed wiring board according to claim 9, wherein in the resin film cutting step, a cut-in is formed up to the outer layer base material by the cutting of the temporary fastening resin film.

11. The method for manufacturing a multilayer printed wiring board according to claim 9, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

12. The method for manufacturing a multilayer printed wiring board according to claim 10, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

13. The method for manufacturing a multilayer printed wiring board according to claim 9, wherein the temporary fastening resin film is constituted from polyimide resin, and comprises a surface that can be bonded to the interlayer adhesive layer.

14. The method for manufacturing a multilayer printed wiring board according to claim 13, wherein the temporary fastening resin film is a polyimide film in which a heat sensitive adhesive has been applied to a surface that faces the interlayer adhesive layer.

15. The method for manufacturing a multilayer printed wiring board according to claim 9, wherein the lead portion corresponding resin film is formed extended to the outside of the outer circumferential edge of the lead pattern portion.

16. A method for manufacturing a multilayer printed wiring board, the multilayer printed wiring board being provided with a flexible inner layer base material having an inner layer circuit pattern portion and a lead pattern portion extended from the inner layer circuit pattern portion, and an outer layer base material having an outer layer circuit pattern portion layered on the inner layer circuit pattern portion, the method comprising:
an inner layer pattern formation step of pattering a conductor layer of the inner layer base material to form the inner layer circuit pattern portion and the lead pattern portion,
an interlayer adhesive layer formation step of forming an interlayer adhesive layer on the outer layer base material,
a resin film formation step of forming a lead portion corresponding resin film that corresponds to the lead pattern portion on the surface of the interlayer adhesive layer,
a base material layering step of layering the outer layer base material on the inner layer base material via the interlayer adhesive layer, with the position of the lead portion corresponding resin film matched to the position of the lead pattern portion,
an outer layer pattern formation step of pattering a conductor layer of the outer layer base material layered on the inner layer base material to form the outer layer circuit pattern portion corresponding to the inner layer circuit pattern portion, and
an outer layer base material removal step of separating the lead portion corresponding resin film from the inner layer base material to remove the interlayer adhesive layer and the outer layer base material layered on the lead portion corresponding resin film.

17. The method for manufacturing a multilayer printed wiring board according to claim 2, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

18. The method for manufacturing a multilayer printed wiring board according to claim 3, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

19. The method for manufacturing a multilayer printed wiring board according to claim 4, comprising, before the outer layer base material removal step, an outer circumference edge formation step of cutting the layered circuit pattern portion comprising the inner layer circuit pattern portion and the outer layer circuit pattern portion, and the lead pattern portion, from the surrounding inner layer base material and outer layer base material, thus forming an outer circumferential edge of the layered circuit pattern portion and the lead pattern portion.

20. The method for manufacturing a multilayer printed wiring board according to claim 2, wherein the lead portion corresponding resin film is constituted from polyimide resin, and comprises a surface that can be bonded to the interlayer adhesive layer.
